(19) United States
(12) Patent Application Publication
(10) Pub. No.: US 2013/0235895 A1
(43) Pub. Date: Sep. 12, 2013

(54) LASER LIGHT SOURCE, LASER PROCESSING DEVICE, AND SEMICONDUCTOR PROCESSING METHOD

(71) Applicants: Kiminori Mizuuchi, Ehime (JP); Susumu Takagi, Ehime (JP)

(72) Inventors: Kiminori Mizuuchi, Ehime (JP); Susumu Takagi, Ehime (JP)

(73) Assignee: PANASONIC CORPORATION, Osaka (JP)

(21) Appl. No.: 13/884,226

(22) PCT Filed: Nov. 17, 2010
(86) PCT No.: PCT/JP2010/006750

§ 371 Date: May 8, 2013

(51) Int. Cl. H01S 3/11; H01L 21/30

(52) U.S. Cl. CPC H01S 3/11; H01L 21/30
USPC 372/92; 438/795

(57) ABSTRACT

A laser light source (100) according to the present invention includes a laser resonator (150) including a fiber (107) containing a laser active medium and a fiber grating (105, 160) coupled to each of two ends of the fiber (107); an pumping laser light source (104) for emitting pump light into the laser resonator (150); a driving current supply circuit (102) for supplying a pulse-like driving current to the pumping laser light source (104); and a wavelength conversion element (101) for converting a wavelength of laser light which is output from the laser resonator. The laser resonator (150) generates laser light including a principal pulse and a plurality of superimposing pulses which are superimposed on the principal pulse, in accordance with incidence of the pump light; and converted light having the wavelength of each of the principal pulse and the superimposing pulses shortened is generated by the wavelength conversion element (101).

### TECHNICAL FIELD

The present invention relates to a laser light source, and specifically to a laser light source appropriately usable for a dot marking device. The present invention also relates to a laser processing device and a semiconductor processing method using the laser light source.

### BACKGROUND ART

Recently, counterfeit products of electronic devices such as semiconductor devices, solar cells and the like are increasing on the market. Such counterfeit products are generally of poor quality. Today, many electronic devices are used for automobiles and medical devices as well as consumer products. A poor-quality counterfeit product incorporated into such a device may influence the safety of the entirety of the device, and thus may impose monetary damages to vendors of authentic products and also spoil safety of the consumers.

For this reason, there is an increasing tendency to assign unique IDs (Identifications) to semiconductor chips. Assignment of IDs can improve the traceability of individual semiconductor chips and thus can eliminate the counterfeit products and also improve the quality of the authentic products. Therefore, active efforts are being made to establish the international standard for assigning dot marks to semiconductor chips.

There are many technologies for marking a character, a numerical figure or a pattern on a surface of a semiconductor element used in an electronic device. For example, according to a known method for forming a highly visible mark while suppressing generation of dust when performing marking, a surface of a semiconductor element is irradiated with a pulsed laser beam to form many minute projections having a height of 1 μm or less (see, for example, Patent Document 1).

However, the minute projections formed by this method are excessively small and are not highly visible. Therefore, one mark is formed by combining a plurality of minute projections. Such a mark is identified by use of a difference between an amount of light reflected by a diffuse reflection surface formed by each of the plurality of minute projections and an amount of light reflected by a smooth surface with no minute projections. However, since the difference between the amount of light reflected by the diffuse reflection surface and the amount of light reflected by the smooth surface is small, it is difficult to distinguish the diffuse reflection surface and the smooth surface around the diffuse reflection surface from each other. Thus, a high visibility is not obtained.

Under this situation, a technology of forming larger projections and forming one dot for dot marking with one projection has been developed. According to this technology, the pulse width and the energy density of a laser beam are each set within a prescribed range so as to adjust the diameter and the energy density of a laser beam spot formed on a surface of the semiconductor element. As a result, a single minute convexed dot having an improved visibility is obtained (see Patent Document 2). When such a minute dot is located at a prescribed position, marking can be provided in a small area of the surface of the semiconductor element.

### CITATION LIST

### Patent Literature

Patent Document 1: Japanese Laid-Open Patent Publication No. 10-4040
Patent Document 2: Japanese Laid-Open Patent Publication No. 2000-223382

### SUMMARY OF INVENTION

### Technical Problem

According to a structure of a conventional laser marking device, it is not easy to form a convexed dot on a surface of a semiconductor element appropriately. According to the conventional method, when the energy density of laser light is set to a value in a very small range, a convexed dot may be occasionally obtained. However, the energy density of laser light directed toward the surface of a semiconductor wafer may vary in accordance with various factors, and is difficult to be controlled precisely.

The present invention made to solve the above-described problem has a main object of providing a laser light source preferably usable for a laser marking device capable of forming a dot mark having an improved visibility.

Another object of the present invention is to provide a laser processing device and a semiconductor processing method using the laser light source according to the present invention.

### Solution to Problem

A laser light source according to the present invention includes a laser resonator (cavity) including a fiber containing a laser active medium and fiber gratings coupled to each of two ends of the fiber; a pumping laser light source for emitting pump light into the laser resonator; a driving current supply circuit for supplying a pulse-like driving current to the pumping laser light source; and a wavelength conversion element for converting a wavelength of laser light which is output from the laser resonator. The laser resonator generates laser light including a principal pulse and a plurality of superimposing pulses which are superimposed on the principal pulse, in accordance with incidence of the pump light; and converted light having the wavelength of each of the principal pulse and the superimposing pulses shortened is generated by the wavelength conversion element.

In a preferable embodiment, the laser resonator performs laser oscillation in a plurality of longitudinal modes and allows the plurality of longitudinal modes to interfere with each other to form the plurality superimposing pulses.

In a preferable embodiment, the pumping laser light source allows the pump light having a rectangular waveform to be incident on the laser resonator based on the driving current; and the laser resonator performs pulse oscillation by the pump light having the rectangular waveform.

In a preferable embodiment, when the laser resonator performs the pulse oscillation, a refractive index of the laser resonator is changed, and the change of the refractive index of the laser resonator changes an effective resonator length of the laser resonator; and a frequency shift of the laser light caused by the change of the effective resonator length is larger than an inter-longitudinal mode interval of the laser resonator.

In a preferable embodiment, the effective resonator length of the laser resonator is changed in accordance with a temperature change of the laser resonator; and a frequency shift of the laser light caused by the change of the effective resonator length is larger than an inter-longitudinal mode interval of the laser resonator.

In a preferable embodiment, an oscillation spectral width Δfa of the laser resonator is larger than 1 GHz and smaller than a frequency permission degree Δfs at which the wavelength conversion element realizes a prescribed conversion efficiency.

In a preferable embodiment, the frequency permission degree Δfs at which the wavelength conversion element realizes the prescribed conversion efficiency is larger than 1 GHz.

In a preferable embodiment, an oscillation spectral width Δfa of the laser resonator is larger than m·df, which is a logical product of the inter-longitudinal mode interval df and a number m of the longitudinal modes, and is smaller than a frequency permission degree Δfs at which the wavelength conversion element realizes a prescribed conversion efficiency.

In a preferable embodiment, the wavelength conversion element generates harmonic of the laser light which is output from the laser resonator.

In a preferable embodiment, the laser light source further includes temperature retaining means for retaining a temperature of the wavelength conversion element at a prescribed level.

In a preferable embodiment, the temperature retaining means retains the temperature of the wavelength conversion element at a level at which the conversion efficiency of the wavelength conversion element is decreased to a value in a range of 5% to 50% of a maximum value.

A laser processing device according to the present invention is for irradiating a semiconductor wafer or a semiconductor chip by use of the semiconductor wafer with laser light having a wavelength determined in accordance with a material of the semiconductor wafer, to melt a surface of the semiconductor wafer and thus to form a convexed part. The laser processing device includes any one of the above laser light sources; and an optical system for irradiating the semiconductor wafer or the semiconductor chip with the laser light which is output from the laser light source.

A semiconductor processing method according to the present invention includes the steps of preparing a semiconductor; and irradiating a surface of the semiconductor with pulsed laser light emitted from a laser light source to form a convexed part on the surface of the semiconductor. The laser light source is any one of the above laser light sources.

### Advantageous Effects of Invention

According to the present invention, a highly visible superb minute convexed part can be formed on a semiconductor wafer or a semiconductor chip by use of laser light.

### BRIEF DESCRIPTION OF DRAWINGS

FIG. 1 show a dot formation process; and FIGS. 1(a) through 1(f) respectively show different steps.

FIG. 2 shows a problem which may be caused in a dot formation process.

FIG. 3 shows a waveform of laser light in an embodiment according to the present invention.

FIG. 4 shows a melted pool formed when laser light shown in FIG. 1 is directed.

FIG. 5 is a graph showing the relationship between the pulse amplitude ratio and the dot height.

FIG. 6 shows a laser marking device in Embodiment 1 according to the present invention; and FIG. 6(a) shows an overall structure, and FIG. 6(b) shows a wavelength conversion element and a temperature controller in enlargement.

FIG. 7 shows the principle of a gain switch in an embodiment according to the present invention; and FIG. 7(a) shows a structure of a resonator, FIG. 7(b) shows a change of the pump light intensity along time; FIG. 7(c) shows a change of the internal energy along time; FIG. 7(d) shows a change of the output light along time; and FIG. 7(e) shows a change of the refractive index along time.

FIG. 8 is a graph showing the relationship of the phase matching temperature shift with respect to the amplitude ratio and the output of the harmonic.

FIG. 9 is a graph showing the relationship between the spectral width of a fundamental wave and the conversion efficiency of the wavelength conversion element.

FIG. 10 shows the relationship of the peak power of the principal pulse of the fundamental wave with respect to the peak power of the principal pulse of SHG light and the spectral width of the fundamental wave.

FIG. 11(a) shows a structure of a fiber laser for single polarization which uses a polarization-maintaining fiber, FIG. 11(b) shows a cross-sectional structure of a grating fiber, and FIG. 11(c) shows the relationship between reflection spectra of polarizations of the grating fibers.

FIG. 12 shows a change, along time, of the average value of SHG output obtained by converting light from a fiber laser; and FIG. 12(a) shows characteristics of a fiber laser with no superimposing pulse being superimposed, and FIG. 12(b) shows characteristics of a fiber laser with superimposing pulses being superimposed.

FIG. 13 shows the height and the diameter of a convexed dot.

FIG. 14(a) is a table showing the relationship between the energy density of the laser light at a light collection point and the dot height, and the generation state of minute debris, and FIG. 14(b) is a graph showing the same.

FIG. 15 shows convexed dots formed in an example; and FIG. 15(a) shows a dot formed when the energy density is 2 J/cm², FIG. 15(b) shows a dot formed when the energy density is 2.5 J/cm², and FIG. 15(c) shows a dot formed when the energy density is 5 J/cm².

FIG. 16 shows large debris.

FIG. 17(a) shows a dot formed in a comparative example, and FIG. 17(b) shows a dot formed in the example.

FIG. 18 shows a structure of a marking device in Embodiment 2 according to the present invention.

FIG. 19 shows an example of infrared lens formed by a semiconductor processing method in Embodiment 3 according to the present invention.

FIG. 20 shows a device for producing a solar cell panel in Embodiment 4 according to the present invention.

FIG. 21 shows a method for producing a solar cell panel using the production device shown in FIG. 20.

### DESCRIPTION OF EMBODIMENTS

First, problems which may occur when a dot mark is formed on a surface of a semiconductor element by use of laser light will be described.

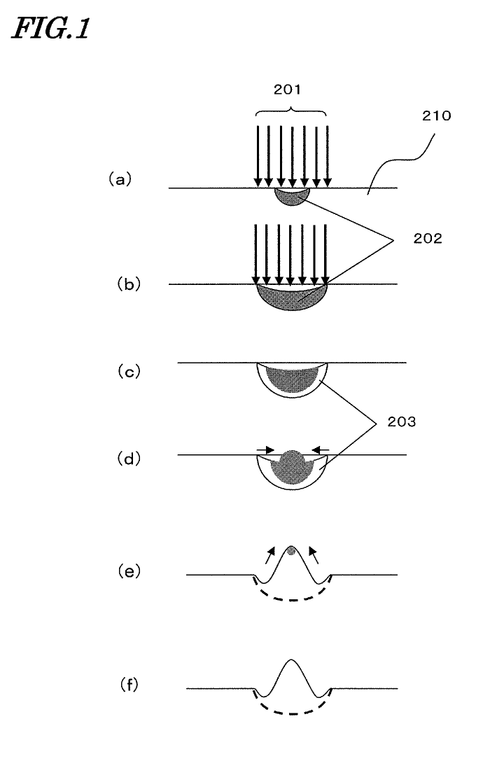

FIGS. 1(a) through 1(f) show an example of process of forming a projection (dot) usable as a dot mark. First, when a semiconductor wafer 210 is irradiated with beam-like laser light 201 having a diameter of several micrometers, the laser light 201 is absorbed and the temperature of a part of the wafer 210 is increased. A part having a temperature exceeding a melting point is melted. The wavelength of the laser light 201 is set to a value at which the target semiconductor absorbs light efficiently. The melted part is called a “melted pool 202” (FIG. 1(a)). When the irradiation with the laser light 201 is continued, the melted pool 202 expands by thermal diffusion (FIG. 1(b)). Since melted silicon has a smaller volume than that of silicon in a pre-melted solid state, the surface of the melted pool 202 is concaved with respect to the surface of the substrate. Nonetheless, a central part of the melted pool is made almost flat because of the surface tension of a liquid phase part. By contrast, a peripheral part of the melted pool has a curvature in the vicinity of a border between a solid phase and the liquid phase. When the irradiation with the laser light 201 is stopped, the supply of the thermal energy to the melted pool 202 is stopped. Therefore, the heat is taken away from the peripheral part, and the melted pool 202 starts solidifying (FIG. 1(c)).

In this case, the peripheral part is solidified along the concaved surface of the melted pool 202, and thus a solidified part 203 is formed in the peripheral part. The solidified part 203 has a surface more recessed than the surface of the substrate. When the time passes, the solidification proceeds from the peripheral part (solidified part 203) toward the central part of the melted pool 202. In this process, a part having the volume increased because of the solidification is concentrated to the central part of the melted pool 202. Therefore, the central part is gradually elevated (FIG. 1(d)). When the entirety of the melted pool 202 is solidified, a convexed dot is formed in the central part (FIG. 1(e)). By such a formation process, a convexed dot in which the peripheral part is recessed and the central part is elevated is formed (FIG. 1(f)).

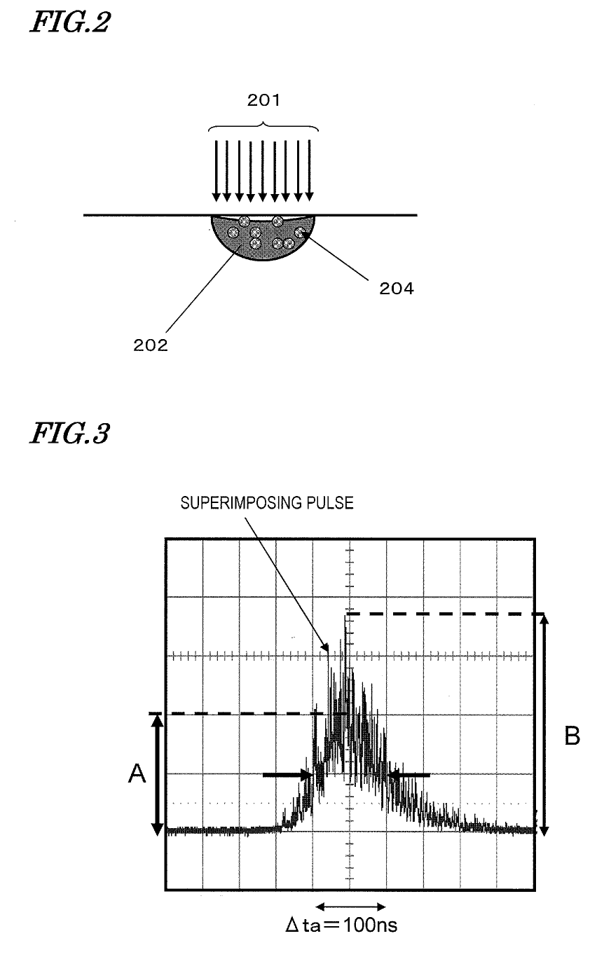

However, when a minute convexed dot is formed by the above-described process, the following problem occurs. Hereinafter, with reference to FIG. 2, the inventor's consideration on the problem will be described.

FIG. 2 shows a state of the melted pool 202 formed by a conventional marking device. For forming a dot having a precise convexed shape, formation and solidification of the melted pool 202 are important factors. The melting state of the melted pool 202 significantly influences the shape of the dot to be formed. The melting state of the melted pool 202 can be found by observing an AFM (Atomic Force Microscope) image, which shows the shape of the dot formed.

An observation of an AFM image of a convexed dot formed by the conventional method shows that there are minute convexed and concaved parts at a surface of the dot (see FIG. 17(a)). These convexed and concaved parts show crystal defects; namely shows that the melted pool 202 includes solid parts (remaining solid parts) 204 which have not been melted, as shown in FIG. 2. The size of the remaining solid parts 204 is typically about 0.01 to 0.5 μm.

The remaining solid parts 204 have a smaller volume than that of a liquid phase and gather at a surface of the melted pool 202. Therefore, after the melted pool 202 is solidified, the convexed and concaved parts are formed at the surface of the dot by the remaining solid parts 204. The remaining solid parts 204 also form crystal defects when solidifying, due to strain against the crystals in the peripheral part. This causes the crystal defects seen at the surface of the dot.

When the melted pool 202 contains many (e.g., 100 or more) remaining solid parts 204, volume contraction by melting is prevented and thus the recess at the surface of the melted pool 202 is decreased. In addition, the remaining solid parts 204 in the vicinity of the surface weakens the surface tension, and thus the recess in the peripheral part of the melted pool is decreased. When the recess of the peripheral part is small, the elevation caused by the volume expansion which is caused by the solidification is small. As a result, the height of the convexed part is decreased. Such a phenomenon is especially conspicuous when the irradiation power of the laser light is weak.

Especially when the energy density (power density) of the laser light 201 directed toward the semiconductor wafer is lower than 2 J/cm², the elevation of the convexed part is significantly low and thus the visibility is poor. By contrast, when the power density is increased, the melting is promoted and the elevation of the convexed part can be made high. However, since the melted pool 202 contains the remaining solid parts 204, drastic bumping occurs locally. As a result, the silicon in the melted pool 202 scatters and spreads around the dot. This decreases the visibility of the dot.

The present inventors recognized such a problem caused by the conventional marking method and studied in order to solve the problem. Hereinafter, an embodiment of the present invention will be described, but the present invention is not limited to the following embodiment.

As described above, for the laser marking technology of a semiconductor wafer (or a semiconductor chip), it is desired to melt and then solidify the minute area at the surface thereof to form a minute convexed part (e.g., a conical convexed port having a diameter of about 5 μm and a height of 0.5 μm) with an appropriate shape. For forming such a minute convexed part by irradiation with laser light, the energy density of the laser light directed toward the semiconductor element needs to be controlled at high precision. Conventionally, for forming a minute dot, a solid-state laser such as a YAG (yttrium aluminum garnet) or the like is used. However, it is not easy to form a minute convexed part of a desired shape with such a laser.

It is conceivable to form a dot by use of a fiber laser. However, a fiber laser has a resonator length (cavity length) which is several tens of times longer than that of a solid-state laser such as a YAG laser or the like and causes oscillation in many longitudinal modes. Therefore, large noise components (high frequency components) are superimposed on the output light. When there are many noise components, it is difficult to control the energy density of the laser light to be directed. Therefore, it is conventionally considered practically difficult and inappropriate to use a fiber laser for forming a minute convexed part of, for example, about 5 μm.

Against such technological common knowledge, the present inventors made active studies on forming a minute convexed part on a surface of a semiconductor wafer by use of a fiber laser. As a result, it was found that when pulsed laser light is used and the amplitude ratio of high frequency noise (superimposing pulse) with respect to a principal pulse and the frequency of the superimposing pulse are set appropriately, a dot mark having a higher visibility can be formed stably than in the case where the conventional solid-state laser is used.

In general, laser light which is output from a solid-state laser may occasionally have a high frequency component corresponding to the superimposing pulse. However, the amplitude ratio of the superimposing pulse with respect to the principal pulse is as low as, for example, about 10%, and the frequency thereof is as low as about several tens of megahertz. In this case, remaining solid parts are easily generated, and thus it is difficult to produce a uniform melted pool. In order to provide a superimposing pulse having a sufficiently high frequency, the resonator length needs to be long. However, when a solid-state laser or a gas laser is used, huge facilities are necessary to provide a resonator length having a sufficient length (several meters or longer), which is not feasible. By contrast, when a fiber laser is used, a resonator of a smaller loss can be obtained by appropriately selecting a laser medium in the fiber. Therefore, a long resonator length can be easily obtained. When a fiber laser having a resonator of an appropriate length is used, a superimposing pulse having a maximum frequency exceeding, for example, 1 GHz can be generated.

However, when a fiber laser is used, there is a limitation on the wavelength of the laser light to be output due to physical restriction on the laser active material. For example, for performing marking on a silicon wafer, it is preferable that the wafer is irradiated with laser light having a wavelength of about 530 nm. However, when only a fiber laser is used, it is difficult to provide laser light of such a wavelength.

In order to form a highly visible dot mark on a silicon wafer or the like, the present inventors used a combination of a fiber laser and a wavelength conversion element. As the wavelength conversion element, for example, a second harmonic generation (SHG) element for outputting light of a wavelength which is half of that of input light can be used.

However, on a wavelength conversion element structured to use second harmonic generation or third harmonic generation, single polarized light needs to be incident. However, output light from a fiber laser is usually non-polarized light. Therefore, a technology for converting the wavelength of the output light from the fiber laser by use of a wavelength conversion element is needed. When a polarizer is inserted into an optical path, single polarized light can be obtained, but the light utilization efficiency is decreased. In this situation, the present inventors produced and used a fiber laser capable of outputting single polarized light without using a polarizer. Such a fiber laser can be produced by, for example, appropriately connecting a prescribed grating fiber to each of two ends of a polarization-maintaining (or polarization-preserving) fiber containing a laser active material. The fiber laser capable of outputting single polarized light will be described later in detail.

When a fiber laser and a wavelength conversion element are used in combination and pulsed laser light having a waveform including an appropriate superimposing pulse is directed, a minute convexed part which forms a dot mark can be formed relatively easily on a material such as, for example, a silicon wafer or the like.

Hereinafter, the principle of a laser marking method in an embodiment according to the present invention will be described.

FIG. 3 shows an output waveform of laser light which is output from a laser light source in this embodiment. In the graph, the horizontal axis represents the time, and the vertical axis represents the intensity of the light. As shown in the figure, the output laser light has a waveform including many high frequency noise components (superimposing pulses) superimposed on a principal pulse. Pulse width Ata of the principal pulse is defined as an average value of full width half maximum of the laser output waveform of about 100 pulses, and is set to, for example, 100 ns as shown in the figure.

It is preferable that many superimposing pulses exceeding the prescribed number are superimposed on one principal pulse. For example, the superimposing pulse frequency is set to 1 GHz or higher so that 100 or more superimposing pulses are superimposed on a principal pulse having a pulse width of 100 ns. Amplitude ratio B/A, which is defined as the ratio of peak output B of the superimposing pulses with respect to peak output A (amplitude) of the principal pulse, is set to, for example, 140% or higher, preferably to 150% or higher. A method for controlling the superimposing pulse frequency and the amplitude ratio B/A will be described later.

Amplitude B of the superimposing pulses is measured as a peak of the laser output waveform of each superimposing pulse as shown in, for example, FIG. 3. Namely, the amplitude B of the superimposing pulses is defined as the maximum value (peak) of an output including the principal pulse and the superimposing pulses in the waveform of the pulsed laser light which is actually directed toward the surface of the semiconductor element.

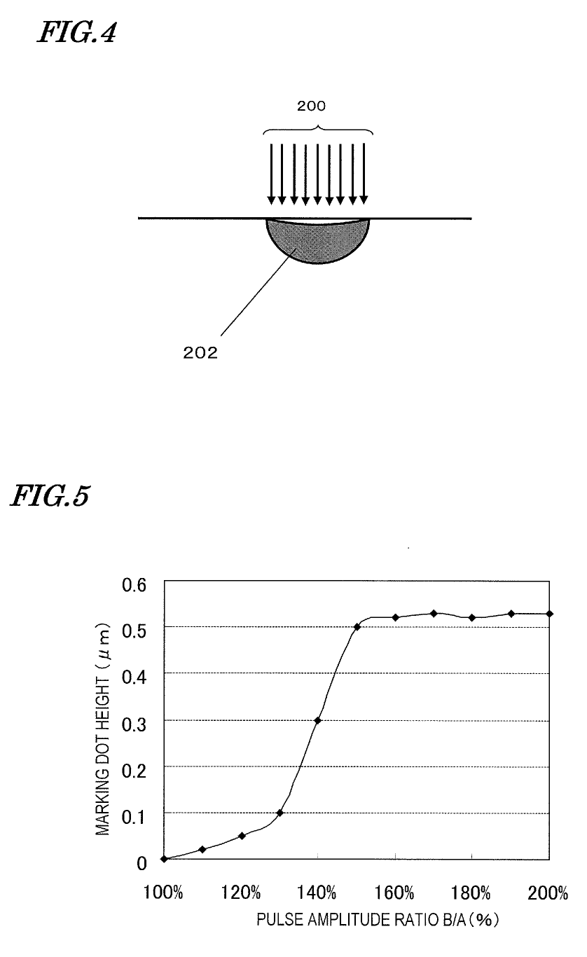

FIG. 4 schematically shows a state of the melted pool 202 which is formed when a silicon wafer is irradiated with laser light 200 having the output waveform shown in FIG. 3.

In the process of a phase change from a solid phase in an initial period of melting to a liquid phase, post-melting liquid parts and non-melted solid parts (remaining solid parts) are present in a mixed state. The remaining solid parts have a smaller specific gravity than that of melted silicon, and therefore float up toward the surface of the melted pool by heat convection.

In this process, the supplied energy is used as phase change energy from the solid phase to the liquid phase. Thus, the temperature is stabilized. However, the remaining solid parts have a structure which is more difficult to be melted than the other part of silicon at this temperature. Therefore, in the phase change process, mere supply of energy from outside does not melt the remaining solid parts.

However, when laser pulses having a sufficiently high frequency for the fundamental laser pulse (principal pulse), for example, laser pulses having a frequency of 1 GHz or higher are superimposed, the solid parts can be easily melted. When laser light including the superimposing pulses as shown in FIG. 3 is directed, the melted pool 202 with no remaining solid part can be formed within a short time.

What is important is the amplitude ratio of the superimposing pulses with respect to the principal pulse. The maximum frequency of the superimposing pulses is also important. The superimposing pulses include a plurality of pulses having different frequencies (frequency components). Therefore, accurately describing, the frequency of the superimposing pulses is defined by a prescribed frequency width. In this specification, the maximum frequency component among the frequency components of the superimposing pulses is referred to as the “maximum frequency”.

Hereinafter, the relationship of the amplitude ratio of the superimposing pulses with respect to the principal pulse and the maximum frequency of the superimposing pulses vs. the height of the formed convexed dot will be described.

As described above with reference to FIG. 3, where the amplitude of the principal pulse is A and the amplitude of the superimposing pulses is B, the amplitude ratio of the superimposing pulses with respect to the principal pulse is represented by B/A. In the case where the pulse width of the principal pulse is about 100 ns, the maximum frequency of the superimposing pulses is preferably set to 1 GHz or higher.

FIG. 5 shows the relationship between the pulse amplitude ratio B/A and the height of the dot. In the example shown in FIG. 5, a convexed dot is formed by directing laser light of a low power density (2 J/cm²) in order to allow the influence of the pulse amplitude ratio to be observed easily.

As can be seen from the graph in FIG. 5, when the amplitude ratio B/A is 130% or lower (i.e., the amplitude of the superimposing pulses is relatively small), the height of the formed convexed dot is as low as about 1.0 μm. When the amplitude ratio B/A exceeds 150%, the height of the formed convexed dot is generally constant at a value exceeding 0.5 μm.

A conceivable reason for this is the following. When the amplitude ratio B/A is relatively low (in this example, 130% or lower), many solid parts remain in the melted pool; whereas when the amplitude ratio B/A exceeds a prescribed value (in this example, 150%), the melted pool does not contain the solid parts and is uniform.

In the example in FIG. 5, when the pulse amplitude ratio is 150% or higher, the height of the dot exceeds 0.5 μm. Needless to say, the present invention is not limited to this example. A pulse amplitude ratio preferable to obtain an appropriate dot is adequately selected in accordance with, for example, the power density of the laser light to be directed. As long as a sufficient visibility is obtained, the height of the dot is not limited to 0.5 μm or higher and may be lower than 0.5 μm.

What is important is that in order to form a convexed dot having an improved visibility and a desired height and shape, the amplitude of the superimposing pulses is adjusted with respect to the amplitude of the principal pulse.

Now, an influence exerted on the shape of the dot by the maximum frequency of the superimposing pulses will be described. In the case where the pulse width Δta of the principal pulse was 100 nanoseconds, when the maximum frequency of the superimposing pulses was set to 1 MHz to 100 MHz, a sufficient dot height was not obtained. A conceivable reason for this is as follow: since the number of the superimposing pulses was not sufficient for the maim pulse, the melted pool was not appropriately formed and as a result, a dot having a desired shape was not formed. By contrast, in the case where the pulse width of the principal pulse was 100 nanoseconds, when the maximum frequency was set to 1 GHz or higher, a dot of a superb height was obtained.

Nonetheless, according to the present invention, the maximum frequency of the superimposing pulses is not limited to 1 GHz or higher, and may be appropriately set in accordance with the pulse width of the principal pulse or the like. The maximum frequency is preferably 500 MHz or higher, more preferably 1 GHz or higher.

When laser light including a principal pulse and a plurality of superimposing pulses is directed as described above, a preferable dot having a desired shape and height can be formed by appropriately selecting the amplitude of the superimposing pulses with respect to the amplitude of the principal pulse (amplitude ratio) and the maximum frequency of the superimposing pulses. It is preferable that the amplitude and the frequency of the superimposing pulses are defined based on the amplitude and the pulse width of the principal pulse. When the amplitude and the frequency of the superimposing pulses are set with respect to those of the principal pulse, a minute convexed part can be appropriately formed.

### Embodiment 1

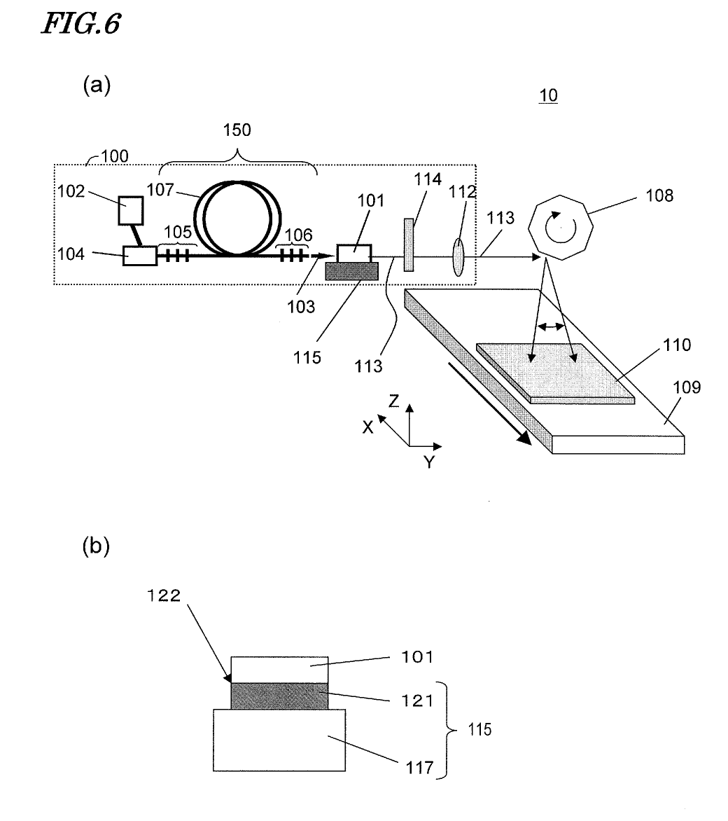

Hereinafter, with reference to FIGS. 6(a) and 6(b), a marking device 10 using a laser light source 100 in Embodiment 1 will be described.

As shown in FIG. 6(a), the marking device 10 includes the laser light source 100, a scan mirror 108, and a stage 109. Laser light 113 emitted (output) from the laser light source 100 is directed toward a semiconductor wafer 110 located on the stage 109 via the scan mirror 108. Owing to this, a minute convexed dot is formed on the semiconductor wafer 110. In FIG. 6(a), the semiconductor wafer 110 is shown as being a square plate. Needless to say, the semiconductor wafer 110 may be a circular plate. In this example, the semiconductor wafer 110 is the processing (marking) target. The processing target may be a semiconductor chip.

The laser light source 100 includes an LD power supply 102, an pumping LD (exciting semiconductor laser) 104, and a laser resonator 150. The laser resonator 150 includes a double clad fiber 107 and fiber gratings 105 and 106 respectively provided at two ends of the double clad fiber 107.

As the double clad fiber 107, for example, a double clad polarization-maintaining fiber including a core part doped with Yb as a rare earth element is usable. The fiber has a length of, for example, 16 m.

In the case where Yb is contained as the laser active material, fundamental wave light 103 of 1050 to 1170 nm can be oscillated optionally. In this embodiment, the fiber doped with Yb is used. Laser active materials which can be contained in the fiber include rare earth elements such as Er, Pr, Nd, Tm, Ho and the like, and a mixture thereof. The oscillation wavelength can be optionally selected by changing the rare earth element with which the fiber is doped.

The pumping LD 104 is driven by the power supply 102. A driving current modulated to be pulse-like is applied to the pumping LD 104 by the power supply 102, and thus pulse-like pump light having a wavelength of, for example, 915 nm is output from the pumping LD 104. The pump light is incident on the double clad fiber 107 via the fiber grating 105, and excites the laser active material used to dope the core part of the fiber 107.

The light generated inside the double clad fiber 107 is reflected by the fiber gratings 105 and 106 and is amplified while reciprocating in the laser resonator 150. In this manner, laser light (hereinafter, may be referred to as “fundamental wave 103”) is oscillated by induced emission from the laser resonator 150. In the case where pump light having a prescribed pulse-like (rectangular) waveform is used, the fundamental wave 103 is pulsed laser light.

The laser light source 100 further includes a wave conversion element 101 to which the fundamental wave 103 is input, a temperature controller 115 associated with the wave conversion element 101, and an attenuator 114 and a light collection lens 112 which are provided for the laser light which is output from the wave conversion element 101.

The fundamental wave 103 output from the laser resonator 150 is converted to second harmonic 113 having a wavelength half of that of the fundamental wave 103 by the wave conversion element 101, the temperature of which is controlled by the temperature controller 115. The second harmonic 113 output from the wave conversion element 101 has an intensity thereof adjusted by the attenuator 114 and then is collected by the lens 112. The second harmonic 113 is directed to an optional position on the semiconductor wafer 110 by adjustment of the scan mirror 108 and the stage 109. In this manner, marking is performed on the semiconductor wafer 110.

In this embodiment, a silicon wafer is used as the semiconductor wafer 110. For performing marking on the silicon wafer, it is important to appropriately select the wavelength of the laser light to be directed thereto. For example, with a YAG laser, which is commonly used, the absorbance of laser light by silicon (wavelength: 1064 nm) is low, and thus the laser light reaches deep inside the silicon. This enlarges the dot. Therefore, it is difficult to form a minute dot having a diameter of about 5 μm. With ultraviolet light (wavelength: 355 nm), the absorbance thereof by silicon is high, and thus the ultraviolet light is absorbed only in the vicinity of the surface of the silicon wafer. Therefore, the melted pool cannot be formed and transpiration easily occurs at the surface of the silicon wafer. For these reasons, for performing marking on the silicon wafer, the wavelength of the laser light is preferably around 530 nm.

In this embodiment, the laser resonator 150 and the wavelength conversion element 101 are used in combination to provide laser light having a wavelength of about 530 nm. The resonator length is set to be long by use of an optical fiber in the laser resonator 150, so that superimposing pulses having a high frequency and a large amplitude are superimposed on a principal pulse. The wavelength conversion element 150 generates the second harmonic 113 having the wavelength of each of the principal pulse and the superimposing pulse shortened. The silicon wafer is irradiated with the second harmonic 113, and as a result, a minute dot can be formed on the silicon wafer.

While dot marking is performed by use of the second harmonic 113 emitted from the wavelength conversion element 101, the temperature of the wavelength conversion element 101 is controlled by the temperature controller 115 as described above. By such temperature control, the wavelength conversion element 101 performs appropriate wavelength conversion. Hereinafter, the temperature controller 115 will be described in detail.

As shown in FIG. 6(b), the temperature controller 115 includes a copper plate 121 thermally connected to the SHG element 101 and a Peltier element 117 thermally connected to the SHG element 101 via the copper plate 121. The SHG element 101 is produced by use of, for example, a polarization-inverted crystal of Mg-doped LiNbO₃ or Mg-doped LiTaO₃ having a cyclic polarization-inverted structure. The SHG element 101 is bonded to the copper plate 121 by an adhesive 122 in order to have the temperature thereof uniformized. The temperature of the SHG element 101 can be controlled by the Peltier element 115 via the copper plate 121.

The copper plate 121 is used for the following reasons. First, since the thermal conductivity of copper is high, use of the copper plate 121 can improve the thermal conductivity of the SHG element 101. This improves the temperature uniformity of the SHG element 101. In addition, the coefficient of thermal expansion of the SHG element 101 and that of the copper plate 121 are close to each other. Therefore, when the temperature is changed, a stress caused by the thermal expansion difference is suppressed from acting on the SHG element 101. It was found that in the case where aluminum or SUS (stainless steel) having a larger difference in thermal expansion from the SHG element 101 is used, the conversion efficiency of the SHG element 101 is decreased by a temperature change.

It is preferable that the SHG element 101 has a high uniformity of refractive index in a length direction (proceeding direction of light). When a temperature distribution or a refractive index distribution is caused in the SHG element 101, the conversion efficiency is significantly decreased. In the case where the SHG element 101 generates a pulse output having a high peak value, the absorption of SHG light is increased in the SHG element 101. Therefore, a phenomenon that a temperature distribution was caused in the propagation direction of light in the SHG element 101 and the conversion efficiency was decreased was observed. Since the copper plate 121 has a high thermal conductivity, use thereof alleviates the temperature distribution caused by absorption of light by the SHG element 101 and allows a highly efficient conversion characteristic to be maintained.

It is preferable that the adhesive 122 for bonding the SHG element 101 and the copper plate 121 has a high electric insulating property. The SHG element 101 is pyroelectric, and thus electric charges are generated on a surface thereof by a temperature change. However, it was confirmed by experiment that by a rise of mobility of the electric charges generated by the pyroelectric effect, the absorption of light by the SHG element 101 is increased and the element characteristics are deteriorated. Therefore, the insulating property of the surface of the SHG element 101 is important, and thus it is preferable that the adhesive 122 for bonding the SHG element 101 and the copper plate 121 has a high insulating property (e.g., having a resistance of 10¹⁰ Ωcm or higher). When pulsed light having a high peak value is generated, the absorption, which depends on the peak output, is increased. Therefore, the temperature rises by absorption of light by the SHG element 101. Therefore, it is effective to bond the SHG element 101 for pulse generation to the copper plate 121 having a high thermal conductivity.

Hereinafter, a method for superimposing the superimposing pulses having a high amplitude ratio and a high frequency on the principal pulse will be described in detail.

(Composite Interference of Beat Noise)

“Beat noise” is amplitude noise caused by inter-longitudinal mode interference. When beat noise is allowed to interfere more compositely, noise components having a large amplitude can be superimposed on the principal pulse. Hereinafter, the principle will be described.

A general laser oscillates in a multimode state where the oscillation mode includes a plurality of longitudinal modes. Inter-longitudinal mode interval dλ at this point is represented by the following expression (1).

dλ=λ²/L (expression 1)

Here, λ is the central wavelength of the laser oscillation, and L is the resonator length. Expression (1) can be represented by expression (2) by use of frequency df.

df=C/2L (expression 2)

Here, C is the light velocity.

In general, a spectral width of laser light can be represented by use of length Δλ or by use of frequency λf. The relationship between the length Δλ and the frequency Δf is represented by the following expression (3).

Δf=Δλ*C/λ² (expression 3)

In the following description, the spectral width is represented by Δf, which is the unit of frequency.

The oscillation spectrum of laser light has a certain spectral width Δfa with the fundamental oscillation frequency f₀ at the center. In the spectral width Δfa, there are a plurality of longitudinal modes at an interval of df. Number m of the longitudinal modes in the oscillation spectrum is represented by expression (4). The terms “in the spectral width” refers to full width half maximum of the spectrum intensity.

m=Δfa/df (expression 4)

When there are a plurality of longitudinal modes, beat noise is generated by inter-mode interference. Beat noise is generated by a frequency corresponding to a difference between different longitudinal modes. Namely, frequency fb of the beat noise includes a frequency component corresponding to a difference between frequencies f1 and f2 of two different longitudinal modes, namely, a frequency component of fb=f1−f2. Among the frequency components of the beat noise, the minimum frequency component corresponds to the interval df between adjacent longitudinal modes. The maximum frequency of the beat noise corresponds to the spectral width Δfa of the laser light. Therefore, the beat noise has a frequency component of C/L to Δfa.

In a general solid-state laser, the S/N ratio of the beat noise is as low as about several percent. However, in a fiber laser, usual beat noise components interfere with each other compositely, and thus the amplitude is amplified. Therefore, unlike with a general solid-state laser, the fiber laser provides beat noise having an S/N ratio which is as high as about 30%.

A fiber laser has a long resonator length. As a result, the inter-longitudinal mode interval df is extremely narrow. For example, where the resonator length is 10 m, the wavelength is 1 μm, and the spectral width Δfa is 30 GHz (100 pm in wavelength unit), inter-longitudinal mode interval df=0.03 GHz (dλ=0.1 pm). Namely, there are 1000 longitudinal modes (m=1000) in the spectral width Δfa.

In this case, the beat noise is present with a wide frequency range of 0.03 GHz to 30 GHz. 1000 longitudinal modes interfere with each other to form beat noise. Therefore, the frequency and the phase of the generated beat noise are of huge values. Beat noise components further interfere with each other compositely, and as a result, superimposing pulses having a high amplitude ratio (e.g., about 140%) are generated.

In this manner, when a fiber laser oscillating in many longitudinal modes is used, beat noise components interfere with each other. Thus, superimposing pulses having a high frequency and a high amplitude ratio with respect to the principal pulse are obtained. The frequency of the beat noise components interfering with each other depends on the frequency component the pre-interfere beat noise components. Therefore, the maximum frequency of the superimposing pulses is the laser oscillation spectral width Δfa, which is the maximum frequency of the beat noise.

In order to sufficiently cause such composite interference of beat noise components, the fiber length of the fiber laser (resonator length) is preferably 5 m or longer, more preferably 10 m or longer.

In this embodiment, in order to improve the upper limit of the frequency band of the superimposing pulses (maximum frequency) to a desired level or higher, the spectral width of the light reflected by the fiber gratings 105 and 106 in the laser resonator 150 shown in FIG. 6(a) is expanded.

Usually, the wavelength conversion element 101 can convert only the light in a specific wavelength range. Therefore, the spectral width of the light reflected by the fiber gratings is made narrow, so that the oscillation wavelength range of the resonator 150 is set to be narrow. Owing to this, the wavelength conversion efficiency of the wavelength conversion element 101 can be improved.

By contrast, in this embodiment of the present invention, in order to allow high frequency noise (superimposing pulses) having a prescribed frequency to be generated easily, the fiber gratings 105 and 106 are adjusted to make the oscillation wavelength range relatively wide. Owing to this, a minute convexed part having a desired shape can be formed relatively easily.

In a general pulse fiber laser which uses a dope fiber as an amplifier and amplifies seed light by the doper fiber, high frequency superimposing pulses are not generated for the following reason. When a dope fiber is used as an amplifier, the dope fiber does not include a fiber resonator structure having a mirror structure provided at both of two ends of the dope fiber. Therefore, many longitudinal modes, which would be generated in the fiber resonator, are not generated, and thus high-frequency superimposing pulses formed by inter-mode interference are not generated.

(Effect of Gain Switch)

In order to increase the amplitude ratio of the superimposing pulses with respect to the principal pulse, it is also effective to significantly change the refractive index of the resonator while pulsed laser light is being generated. In order to realize such a refractive index change, pulsed laser light oscillation by a gain switch described below can be used.

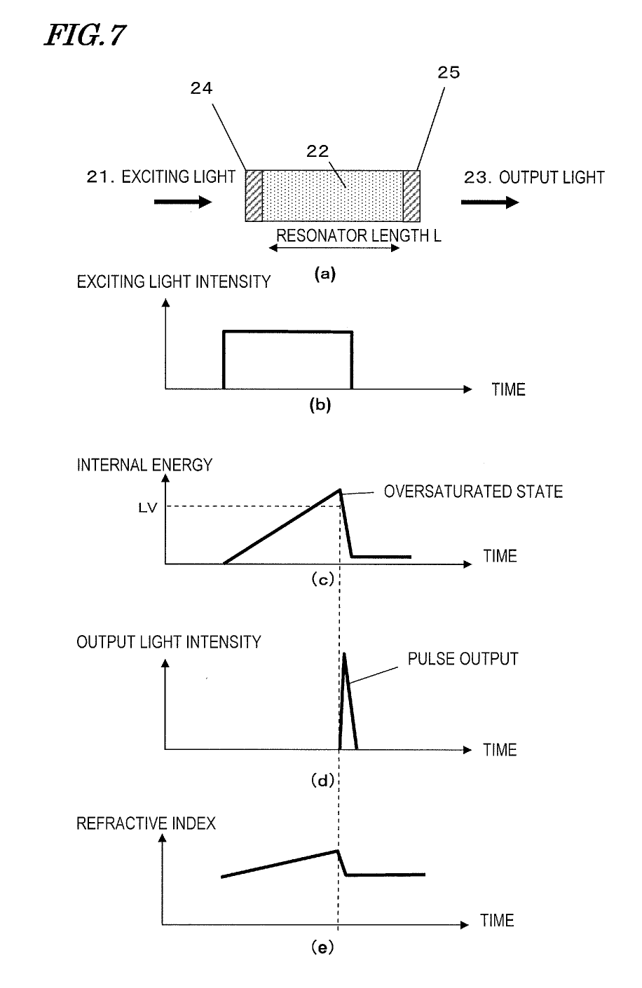

Hereinafter, with reference to FIGS. 7(a) through 7(e), the principle of pulsed light generation by a gain switch will be described.

As shown in FIG. 7(a), the resonator includes a laser medium 22 formed of a Yb-doped fiber and fiber gratings 24 and 25 acting as mirrors. Pumping light 21 is incident on the resonator from one of two ends of the fiber. The pumping light 21 is, for example, laser light having a wavelength of 915 nm which is output from an pumping light source such as a semiconductor laser device (LD) or the like.

FIG. 7(b) shows a change of intensity of the pumping light 21 along time. The vertical axis represents the intensity of the pump light, and the horizontal axis represents the time. FIG. 7(c) shows a change of energy accumulated inside the laser medium 22.

When pulse-like pump light having a rectangular waveform is input to the fiber as shown in FIG. 7(b), the internal energy of the laser medium is increased as time passes as shown in FIG. 7(c). When the excitation of the laser medium proceeds, the internal energy exceeds laser oscillation level LV and is put into an oversaturated state.

In the state where the energy accumulated in the fiber exceeds the laser oscillation threshold value LV, laser oscillation starts suddenly. At this point, the energy accumulated in the oversaturated state is released at one time. Therefore, as shown in FIG. 7(d), pulsed light is generated. At this point, the energy accumulated in a population inversion is released at one time in the resonator. This is the principle of generating pulsed light by a gain switch in this embodiment. In this embodiment, the pump light is controlled such that the incidence thereof on the resonator is stopped almost simultaneously with the output of the pulsed light from the resonator (see FIG. 7(b)).

The present inventors paid attention to that while the pulsed light is being generated by the gain switch, the state of the internal energy in the laser medium significantly changes. The internal energy increases as the excited state density in the population inversion state formed by excited electrons increases. When laser oscillation is caused by the gain switch, as shown in FIG. 7(c), the population inversion rapidly changes from an oversaturated state to a state close to zero. At this point, by the significant change of the population inversion state, the refractive index of the resonator is changed as shown in FIG. 7(e). As can be seen from FIG. 7(e), the refractive index is significantly changed in the resonator at the timing when the laser oscillation is caused.

By the high-speed refractive index change thus caused in the resonator, degeneration of longitudinal modes described below occurs. Owing to this, superimposing pulses having a higher amplitude ratio (e.g., 150% or higher) can be obtained.

(Degeneration (Coupling) of Longitudinal Modes)

As described above, the refractive index of the resonator is rapidly changed by oscillation of pulsed light caused by use of a gain switch. At this point, the effective resonator length is changed. The effective resonator length is also changed by a temperature change inside or outside the resonator. Herein, the “effective resonator length” is an actual length of the resonator which is changed in accordance with the temperature or the like, or an optical distance (optical path length) in the resonator which is changed by a change of the refractive index. By the change of the effective resonator length, the property of the laser light which is output from the resonator may be changed.

When the effective resonator length is changed, degeneration of the longitudinal modes occurs. The “degeneration of the longitudinal modes” is that the frequency of the longitudinal modes is shifted by external disturbance and adjacent longitudinal modes are coupled to each other. When the degeneration of the longitudinal modes occurs, the amplitude change of the longitudinal modes is increased.

Hereinafter, the degeneration (coupling) of the longitudinal modes which occurs when the effective resonator length is changed will be described in more detail.

The effective resonator length may be changed by a temperature change outside or inside the resonator. The effective resonator length is also changed when the refractive index is changed as described above. At this point, the Doppler effect is caused by the change of the resonator length, and thus the frequency of light is shifted. When the magnitude of the frequency shift is larger than the inter-longitudinal mode interval, the longitudinal modes may have a matching frequency and thus the degeneration of the longitudinal modes occurs.

When the degeneration of the longitudinal modes occurs, different longitudinal modes are coupled to each other. When energy coupling occurs between the longitudinal modes, the amplitude of light which is oscillated in the longitudinal modes is increased. As a result, the amplitude ratio of the superimposing pulses is increased.

A condition for causing the degeneration of the longitudinal modes is that the frequency shift caused by the Doppler effect is larger than the inter-longitudinal mode interval df. This condition can be represented by the following expression (5) based on the frequency shift by the Doppler effect (ΔnL/Δt)/λ and the expression (2).

(ΔnL/Δt)/λ>C/L (expression 5)

This can be simplified as the following expression (6).

Δn/Δt>λC/L² (expression 6)

Here, Δn is the refractive index change, λ is the wavelength, C is the light velocity, and L is the resonator length.

From this expression, it is understood that the degeneration of the longitudinal modes is caused by increasing the refractive index change Δn inside the resonator and the resonator length L. Therefore, the degeneration of the longitudinal modes can be easily caused by significantly changing the refractive index by a gain switch in a fiber laser having a long resonator length.

When the fiber laser and the gain switch are combined in this manner, the degeneration of the longitudinal modes occurs as well as the composite interference between the beat noise components. As a result, superimposing pulses having a high amplitude ratio can be generated. In order to cause the degeneration of the longitudinal modes, a narrow inter-longitudinal modes and many longitudinal modes are necessary. Thus, the inter-longitudinal modes interval is preferably 1 pm or narrower, and the number of the longitudinal modes is preferably 100 or larger. In order to fulfill these conditions, it is appropriate to set the resonator length to 5 m or longer. By use of a fiber laser, a long resonator length can be easily realized.

A combination of a general solid-state laser and a gain switch does not generate superimposing pulses having a high amplitude ratio for the following reason. A solid-state laser has a resonator length of about 0.1 m. Where the wavelength of the principal pulse is 1 μm and Δλf is 100 pm, dλ is 10 pm, df is 3 GHz, the number m of the longitudinal modes is 10, and the frequency of the beat noise is 3 GHz to 30 GHz. Therefore, superimposing pulses having a high amplitude ratio are not generated.

(Increase of Amplitude Ratio by Control on the Element Temperature)

Now, another method for increasing the amplitude ratio of the superimposing pulses by use of a combination of the fiber laser and the wavelength conversion element (SHG element in this embodiment) will be described.

The present inventors found that the amplitude ratio of the light converted by the wavelength conversion element depends on the difference between a phase matching temperature of the wavelength conversion element and the actual temperature of the wavelength conversion element (i.e., depends on a phase matching temperature shift). Owing to this, it is made possible to increase the amplitude ratio by controlling the temperature of the wavelength conversion element. The “phase matching temperature shift” is the element temperature at which the SHG output is maximum, and is determined by the characteristics of a nonlinear optical crystal for the SHG, the wavelength to be converted, and the cycle of the polarization-inverted structure formed in the SHG element.

In the case where a nonlinear optical crystal for generating harmonic is used as the wavelength conversion element, in order to increase the output of the harmonic, it is necessary that the refractive index of the nonlinear optical crystal with respect to the incident light should match the refractive index thereof with respect to the generated harmonic (phase matching condition). In order to maintain the refractive index of the nonlinear optical crystal at an appropriate value, it is important to maintain the temperature of the nonlinear optical crystal in a prescribed range.

In this embodiment, the element temperature is not matched to the phase matching temperature, namely, is kept different from the phase matching temperature, so as to cause a phase matching temperature shift. This can increase the amplitude ratio of the superimposing pulses with respect to the principal pulse. Hereinafter, an influence exerted on the phase matching temperature shift on the amplitude ratio will be described.

As described above, when an optimum condition under which the conversion efficiency is maximum (phase matching temperature) is different from the element temperature, the amplitude ratio of the superimposing pulses is increased. This indicates that the superimposing pulses of the fiber laser causes an intensity modulation and also a wavelength change. The wavelength of the superimposing pulses is changed within a wavelength range having the spectral width Δfa of the fiber laser. It is considered that when the element temperature is shifted from the phase matching temperature, the wavelength dependence of the SHG output is increased, and therefore the amplitude ratio of the pulses is increased.

The superimposing pulses accompany a wavelength change of the fundamental wave. Therefore, at the same time as the change of the output of the fundamental wave, the wavelength of the fundamental wave is changed. When the wavelength of the fundamental wave is changed, the wavelength conversion efficiency is changed, and therefore the SHG output is changed. This change is added to the amplitude of the superimposing pulses, and therefore the amplitude ratio is increased. At or the vicinity of the phase matching temperature, the output change caused by the wavelength change increases along with the phase matching temperature shift. Therefore, the amplitude ratio of the superimposing pulses is increased along with the phase matching temperature shift.

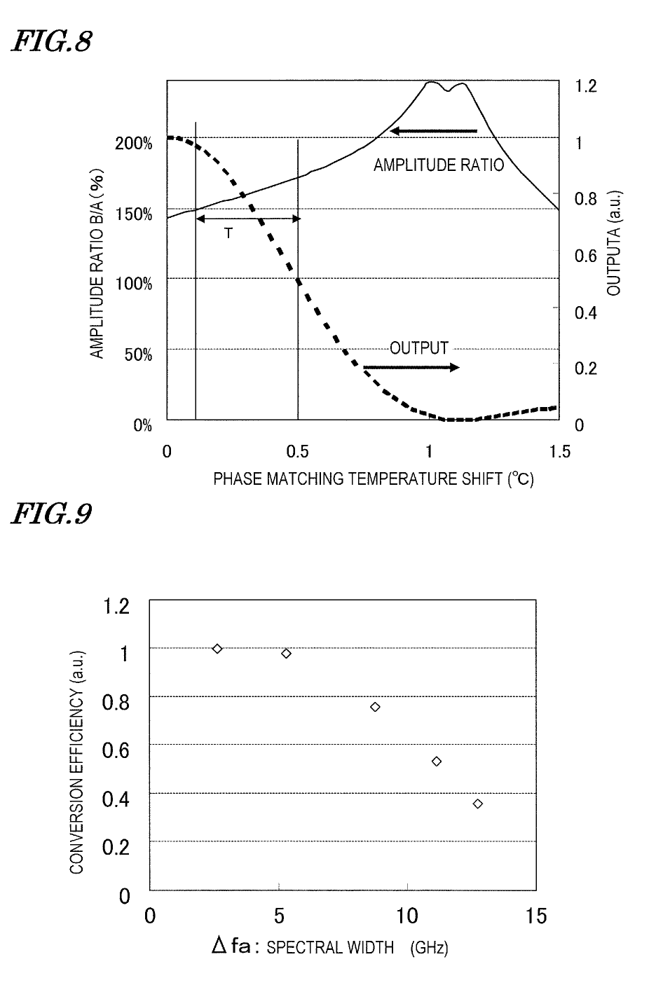

FIG. 8 shows the relationship between the phase matching temperature shift and the pulse amplitude ratio B/A. FIG. 8 also shows the relationship between the phase matching temperature shift and the output A of the light emitted from the wavelength conversion element. The horizontal axis represents a shift of the phase matching temperature from the optimum value. The phase matching temperature is optimum at 0° C., and the shift is represented in term of the temperature. In FIG. 8, the solid line represents the amplitude ratio, and the dashed line represents the output of the emitted light (second harmonic) in terms of the relative intensity. FIG. 8 shows a case where the length of the wavelength conversion element is 25 mm, and a fundamental wave having a wavelength of 1064 nm is converted to harmonic having a wavelength of 532 nm. In this example, the spectral width Δfa is 5.3 GHz (20 pm).

As shown in FIG. 6(b), the temperature of the wavelength conversion element 101 can be controlled by the Peltier element 117. The temperature of the SHG element 101 was controlled by the Peltier element 117 to find, as shown in FIG. 8, the relationship between the phase matching temperature shift (difference between the phase matching temperature and the element temperature) and the output A of the principal pulse and also the relationship between the phase matching temperature shift and the amplitude ratio B/A, which is the ratio of the amplitude of the superimposing pulses with respect to the amplitude of the principal pulse. When the phase matching temperature shift is increased, the amplitude ratio of the superimposing pulses is increased by high frequency noise caused by the wavelength change. Therefore, the amplitude A of the principal pulse is decreased, but the amplitude ratio B/A increases along with the phase matching temperature shift.

A range represented by arrow T in FIG. 8 is a range in which the output decrease can be permitted and in which the superimposing pulses having a desired amplitude ratio can be obtained. Hereinafter, a temperature range by which the temperature of the wavelength conversion element is shifted from the phase matching temperature by use of the Peltier element or the like will be described.

As can be seen from FIG. 8, when the phase matching temperature is shifted from the optimum value, the amplitude ratio B/A is increased. When the phase matching temperature is shifted by about 0.1° C., the output A is not decreased almost at all, whereas the amplitude ratio B/A exceeds 150%. When the phase matching temperature is shifted by about 0.5° C., the output A is decreased to about half, whereas the amplitude ratio B/A is increased to 170%. These results well match the relationship between the phase matching temperature and the amplitude ratio B/A obtained by the experiment. The amplitude ratio B/A shown in FIG. 8 was obtained by shifting the phase matching temperature from the optimum value.

More specifically, when the phase matching temperature shift is 0.1° C., the decrease of the conversion efficiency is about 2%. Thus, it was confirmed that the amplitude ratio of the superimposing pulses is higher than 150% stably. When the decreasing ratio of the conversion efficiency is about 2%, dot formation is possible even by use of a fiber laser having a relatively short resonator length. However, when the decreasing ratio exceeds 50%, the output of the second harmonic is drastically decreased and is significantly unstable, which is not preferable. Therefore, the decreasing ratio of the conversion efficiency is preferably 2% to 50% of the maximum value, more preferably in the range of 5% to 20%.

(Combination of the Wavelength Conversion Element and the Fiber Laser)

In the case where a wavelength conversion element and a fiber laser are used in combination, it is preferable that the characteristics of the wavelength conversion element, and the principal pulse and the superimposing pulses output from the fiber laser, fulfill prescribed conditions. The wavelength, conversion element used in this embodiment has the following structure and characteristics: nonlinear optical material: Mg-doped stoichiometric LiTaO₃; polarization inversion cycle: 8 μm; wavelength of the fundamental wave: 1064 nm; wavelength of the second harmonic: 532 nm; and element length: 26 mm. Permission degree of the wavelength conversion element is Δfs. The resonator length of the fiber laser is L, and the spectral width of the oscillated laser light is Δfa.

FIG. 9 shows the relationship between the standardized conversion efficiency, realized by the wavelength conversion element, of pulsed laser light (fundamental wave) generated by use of a gain switch, and the spectral width Δfa of the fundamental wave. The spectral width Δfa represents an average value of the fundamental wave spectral widths measured by an optical spectrum analyzer.

As can be seen from FIG. 9, when the spectral width Δfa of the fundamental wave is 5.3 GHz (20 pm) or less, an almost constant standardized conversion efficiency is obtained. By contrast, when the spectral width Δfa of the fundamental wave exceeds 5.3 GHz, the conversion efficiency starts significantly decreasing. When the spectral width Δfa of the fundamental wave exceeds 10 GHz, the standardized conversion efficiency is decreased to about half.

In order to prevent the decrease of the wavelength conversion efficiency of the pulsed light generated by use of a gain switch, it is desirable that the spectral width Δfa of the pulsed light is a narrow band. Such a permission degree is equal to or less than half of the permission degree of the wavelength conversion of continuous light (10 to 17 GHz). Therefore, in order to perform wavelength conversion of the pulsed light generated by use of a gain switch with high efficiency, a laser light source capable of oscillating a fundamental wave having a narrow band spectrum is required.

The spectral width of the fundamental wave with which the standardized conversion efficiency of the wavelength conversion element is decreased to half is defined as the “wavelength permission degree Δfs” of the wavelength conversion element. In this specification, the wavelength permission degree Δfs corresponds to the spectral width Δfa of pulsed light for which the wavelength conversion efficiency is decreased to half.

In this example, the wavelength permission degree Δfs is 10.6 GHz (corresponding to 40 pm). This indicates that when an average value of the spectral width Δfa of the fundamental wave exceeds 10.6 GHz, the spectrum component which is not converted by the wavelength conversion element is increased, and as a result, the conversion efficiency is significantly decreased. Therefore, in order to realize highly efficient conversion, the average spectral width Δfa of the fundamental wave needs to be narrower than the wavelength permission degree Δfs.

In the meantime, in order to obtain superimposing pulses having a preferable amplitude ratio, it is desirable that the maximum frequency of the superimposing pulses is 1 GHz or higher. As described above, the maximum frequency of the superimposing pulses corresponds to the spectral width Δfa of the fundamental wave (principal pulse).

Therefore, a preferable range of Δfa is defined by the following expression (7).

Δfs>Δfa>1 GHz (expression 7)

Namely, it is desirable that the spectral width Δfa of the pulse output is smaller than the wavelength permission degree Δfs=10.6 GHz of the wavelength conversion element and larger than the frequency 1 GHz. The wavelength permission degree Δfs of the wavelength conversion element is desirably larger than 1 GHz.

In order to generate preferable superimposing pulses, a sufficient number of longitudinal modes (100 or more) needs to be in the spectrum of the fundamental wave. This is for causing composite resonance of the beat noise to increase the amplitude ratio of the superimposing pulses. In the case where the minimum necessary number m of the longitudinal modes is 100, it is preferable that the spectral width Δfa fulfills Δfa>100·df. From this condition expression and expression (2), the following expression (8) is derived.

Δfs>Δfa>100C/L (expression 8)

As can be seen, it is desirable that the spectral width Δfa of the pulsed laser light which is output from the fiber laser is smaller than the wavelength permission degree Δfa of the wavelength conversion element and larger than a logical product of the number m of the longitudinal modes necessary to generate desired superimposing pulses and the inter-longitudinal mode interval df. It is also desirable that the wavelength permission degree Δfs of the wavelength conversion element is larger than the logical product of the number m of the longitudinal modes necessary to generate desired superimposing pulses and the inter-longitudinal mode interval.

The wavelength permission degree Δfs of the wavelength conversion element depends on the element characteristics. The number of longitudinal modes necessary to obtain desired superimposing pulses is changed in accordance with the design of the fiber resonator and the laser active material used for the fiber resonator. Therefore, it is preferable that the fiber resonator is designed in advance so as to be suitable to the wavelength permission degree Δfs of the wavelength conversion element.

The spectral width Δfa of the pulsed laser light which is emitted by the fiber laser is determined by the design of the grating fibers and the like. As can be seen from FIG. 9, the permission degree Δfs of the SHG element is about 10 GHz. When the resonator length of the fiber laser is calculated from expression (8) by use of this value, it is understood that the resonator length L is preferably 2.5 m or longer. It is more preferable that the resonator length L of the fiber laser is set to 5 m or longer.

When the resonator length L of the fiber laser is set to 5 m or longer, the spectral width Δfa fulfilling expression (8) may be 5.3 GHz or less. Namely, even when a fundamental wave having such a relatively narrow spectral width is input to the wavelength conversion element, desired superimposing pulses are obtained. Base on this, the resonator length may be set to 5 m or longer and the spectral width Δfa may be set to 5.3 GHz or less. In this case, pulsed laser light having an appropriate waveform is obtained with an advantage that the standardized conversion efficiency of the SHG element is not decreased almost at all (see FIG. 9).

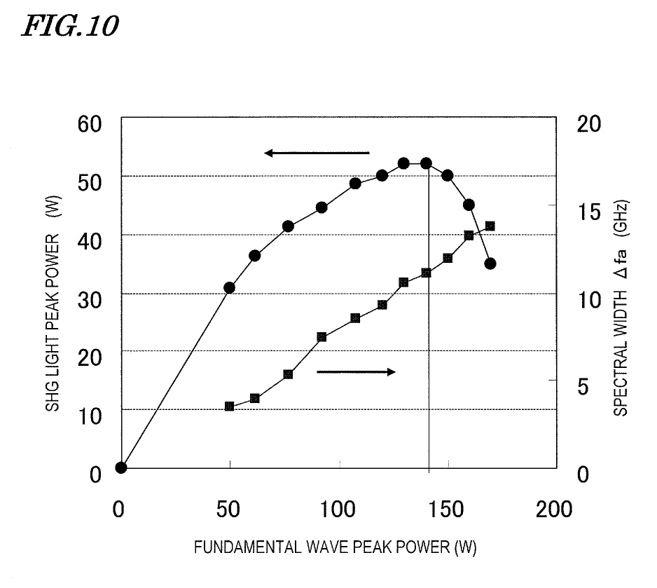

Now, setting of the spectral width Δfa will be described. The spectral width Δfa is the oscillation spectral width of the fiber laser, and is determined by the width of the spectrum which is narrower among the Bragg reflection spectra of the two grating fibers included in the resonator of the fiber laser. In FIG. 10, a curved line represented by ▪ shows the relationship between the peak power of the principal pulse of the fundamental wave and the spectral width thereof. Another curved line represented by shows the relationship between the peak power of the principal pulse of the fundamental wave and the peak power of the principal pulse of the SHG light. The left vertical axis represents the peak power of the principal pulse of the converted SHG light with respect to the peak power of the principal pulse of the fundamental wave, which is infrared light. The right vertical axis represents the spectral width of the infrared light.

The fiber laser used in this measurement is designed such that the resonator length is 16 m and the reflection spectral width of the grating fibers is 3 GHz. The fiber laser is a Yb-doped fiber laser, and generates a gain switch pulse by pump light having a wavelength of 915 nm.

As can be seen from this figure, the spectral width Δfa (▪) of the oscillation light of the fiber laser expands as the peak power of the output pulse is increased. This is caused by an increase of natural light emission component in the fiber laser and the wavelength conversion caused by a nonlinear phenomenon. Therefore, in order to perform highly efficient wavelength conversion, it is preferable that the design value of the Bragg reflection spectrum of the grating fibers is set to 5 GHz or less, in consideration of the wavelength permission degree Δfs (about 10 GHz) of the SHG element. It is more preferable to set the design value to 3 GHz or less.

The “design value of the Bragg reflection spectrum of the grating fibers” is a value of the reflection spectral width in an area in which the fiber laser output is 10 W or less and the oscillation spectral width of the fiber laser is not increased by an influence of the nonlinear decrease or the natural light emission component.

As the spectral width is increased along with an increase of the peak power of the fundamental wave, the peak power of the SHG light () is saturated. This is caused because as shown in FIG. 9, as the spectral width Δfa of the fundamental wave increases, the standardized conversion efficiency is decreased. When the standardized conversion efficiency is decreased, the conversion of the fundamental wave to the SHG light is decreased, and the output of the SHG light is saturated. As can be seen from FIG. 10, when the spectral width of the fundamental wave (▪) becomes 11 GHz or greater, the SHG output () starts decreasing. This value of 11 GHz generally matches 10.6 GHz, which is the wavelength permission degree of the SHG element.

It is preferable to set the peak power of the fundamental wave to an appropriate value based on the relationship between the peak power of the fundamental wave and the SHG output. When the peak power of the fundamental wave exceeds 140 W, the SHG output is decreased. Therefore, the fundamental wave output is preferably 140 W or less. The fundamental wave output is also related to the superimposing pulses. The amplitude ratio of the superimposing pulses with respect to the principal pulse gradually decreases as the peak power of the principal pulse of the fundamental wave increases. Therefore, when the peak power of the principal pulse of the fundamental wave exceeds 160 W, the height of the convexed part of the dot marking formed by the superimposing pulses may be decreased. Therefore, the peak power of the principal pulse of the fundamental wave is preferably 160 W or less.

(Fiber Laser for Oscillating Single Polarized Laser Light)

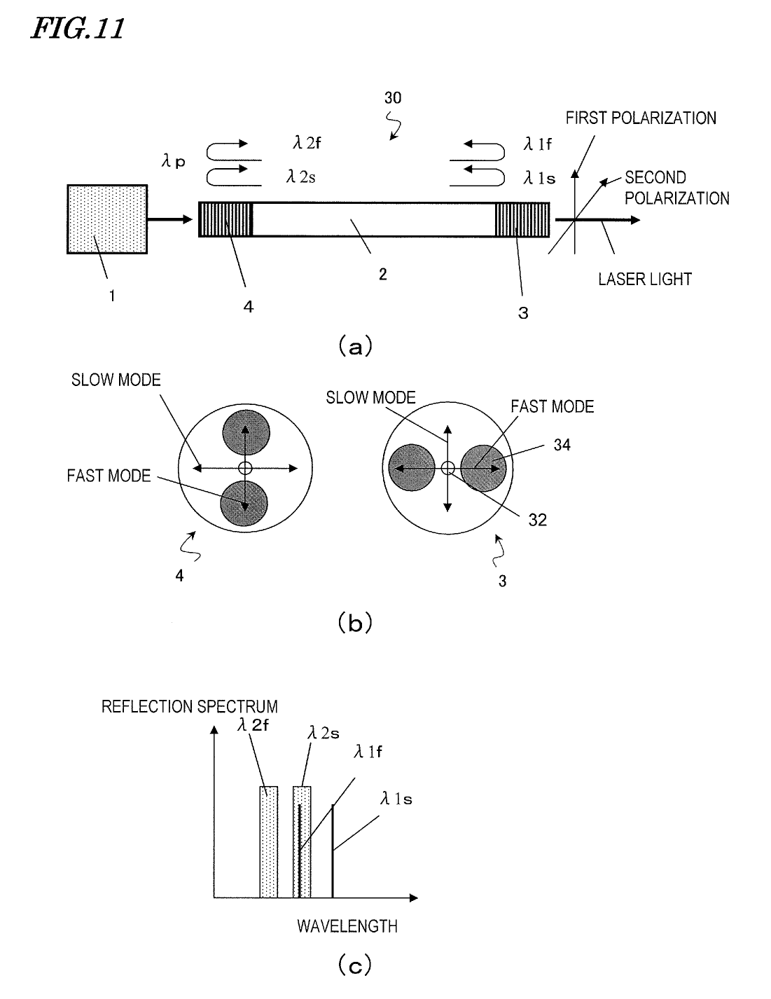

Hereinafter, with reference to FIGS. 11(a) through 11(c), a structure of a fiber laser 30 in this embodiment, which is structured to emit single polarized light, will be described.

FIG. 11(a) is a structural view of the fiber laser 30 produced so as to emit single polarized light. The fiber laser 30 includes a solid-state polarization-maintaining laser fiber 2 doped with a rear earth element, and first and second grating fibers 3 and 4 provided along with the solid-state laser fiber 2 so as to be away from each other by a prescribed distance. The grating fibers 3 and 4 are each formed of a polarization-maintaining fiber having a birefringence index. FIG. 11(b) shows a cross-sectional structure thereof.

As shown in FIG. 11(b), on a side surface of a core 32 for propagating light, parts 34 for applying a stress to the core 32 are located so as to have the core 32 therebetween. Because of the stress applying parts 34, the core 32 exhibits birefringence by a photoelastic effect. In the core 32 having birefringence, polarized light components having polarization axes perpendicular to each other have different propagation constants. As shown in the figure, two polarization modes, namely, a fast mode and a slow mode are present in correspondence with the polarization axes perpendicular to each other. The “fast mode” is a propagation mode of light propagating along a fast axis, and the “slow mode” is a propagation mode of light propagating along a slow axis. Since the two modes have different propagation constants, the coupling of energy between the modes is suppressed. Therefore, when one polarization mode is excited, light is propagated in the core 32 without being coupled to the other polarization mode, in the state where the polarization is preserved. A polarization-maintaining fiber having a structure shown in FIG. 11(b) is known as a PANDA (Polarization-maintaining and Absorption-reducing) fiber.

A feature of the fiber laser 30 in this embodiment is that the first and second grating fibers 3 and 4 are joined to the fiber 2 such that directions of the polarization modes thereof (directions of the fast axes of the grating fibers and directions of the slow axes of the grating fibers) are different from each other by 90°. In the case where the grating fibers (fiber Bragg gratings or FBGs) and 4 provided at both of two ends of the fiber 2 are located such that the polarization modes thereof are perpendicular to each other, light propagating along the fast axis of the first grating fiber 3 propagates along the slow axis of the second grating fiber 4. Light propagating along the slow axis of the first grating fiber 3 propagates along the fast axis of the second grating fiber 4.

The polarization-maintaining fibers used for the grating fibers 3 and 4 each have a refractive index which is changed in accordance with the polarization. Therefore, even when a single cycle grating is formed, the fast mode and the slow mode have different Bragg reflection wavelengths. In the FBGs, the wavelength of light reflected by fulfilling the Bragg conditions is referred to as “Bragg reflection wavelength (or Bragg wavelength)”.

In general, the Bragg reflection wavelength (central wavelength) λ_{b} is defined by λ_{b}=2nΛ (n: effective refractive index of the core; Λ: grating cycle). The Bragg reflection wavelength of the fast mode of the first grating fiber 3 is λ1f, the Bragg reflection wavelength of the slow mode of the first grating fiber 3 is λ1s, and the Bragg reflection wavelengths of the fast mode and the slow mode of the second grating fiber 4 are respectively λ2f and λ2s. In the grating fibers, the Bragg wavelengths of the fast mode and the slow mode have relationships of λ1s>λ1f and λ2s>λ2f because of the difference in the effective refractive index.

In the case of a usual polarization-maintaining fiber, the difference of the Bragg reflection wavelength between the fast mode and the slow mode is about 0.4 nm. The reflectance of the first grating fiber 3 is about 10%, and the reflectance of the second grating fiber 4 is 99% or higher.

When the cycles Λ of the grating fibers are designed such that λ1f=λ2s, the relationship of λ1s>λ1f=λ2s>λ2f is obtained. The Bragg reflection wavelength can be also changed by controlling the temperature of the grating fibers. Utilizing this, the grating fibers may be designed such that λ1f=λ2s by providing prescribed temperature control means. Alternatively, the grating fibers may be designed such that λ1f=λ2s by adjusting the tensile stress on the each fiber to vary the Bragg wavelength.

In this case, λ1s>λ2f. Namely, the Bragg reflection wavelength of the polarization propagating along the slow mode of the first grating fiber 3 is different from the Bragg reflection wavelength of the polarization propagating along the fast mode of the second grating fiber 4. Therefore, in the case where a pair of FBGs are provided such that the directions of the polarization modes are perpendicular to each other as in this embodiment, the Bragg reflection wavelengths of only the polarization propagating along the fast mode of the first grating fiber 3 and the polarization propagating along the slow mode of the second grating fiber 4 match each other.

Now, the operation principle of the fiber laser 30 in this embodiment will be described. Light having a prescribed wavelength λp which is emitted from a pump light source 1 is transmitted through the second grating fiber 4 and is incident on the solid-state laser fiber 2. The pumped light 2p is absorbed in the solid-state laser fiber 2, and excite rare earth ions. As a result, the solid-state laser fiber 2 is put into an excited state. In addition, a resonator structure is provided by the solid-state laser fiber 2 and the first and second grating fibers 3 and 4. Therefore, light amplification occurs by induced emission, and the solid-state laser fiber 2 in the excited state can make laser oscillation.

At this point, in this embodiment, as shown in FIG. 11(c), the fiber laser 30 is designed such that the Bragg wavelength 71f of the fast mode of the first grating fiber 3 matches the Bragg wavelength λ2s of the slow mode of the second grating fiber 4. In order to fulfill a resonance condition, light of the same polarization needs to be reciprocated between mirrors each having the same reflection wavelength. In the structure of this embodiment, only the polarization propagating along the fast mode of the second grating fiber 4 and the polarization propagating along the slow mode of the first grating fiber 3 fulfill the resonance condition. The other polarizations do not fulfill the resonance condition. As a result, laser oscillation occurs with single polarized light, and thus single polarized laser light is output from the fiber by the energy of the pumped light.

Such a single polarization fiber laser in this embodiment is used to provide a pulse oscillation operation by use of a gain switch, and thus the pulse output can increased. Pulse which is output by use of a gain switch is caused by the accumulation of energy in the resonator and release of the energy from the resonator. However, the resonator length of the fiber laser is long. Therefore, if there is a loss (part of energy which is not converted to desired laser light) in the resonator, the energy partially remains and the pulse output is small. As a technique for allowing the fiber laser to act as a single polarization fiber laser, a so-called in-line structure by which a polarization element is inserted into the fiber resonator has been proposed. However, when this technique is used, the loss in the resonator is significantly increased and thus the pulse output is significantly decreased.

By contrast, in the fiber laser in this embodiment described above, the resonator is structured only by fusion of fibers. Therefore, the loss in the resonator is extremely small. In addition, when the polarizations passing the polarization surfaces of the polarization-maintaining fiber which are perpendicular to each other are coupled, the refractive index difference is extremely small (e.g., 10⁻⁴ or less). Therefore, almost no coupling loss is caused. This can decrease the loss in the resonator, and as a result, pulsed light having a large output exceeding 100 W can be oscillated by use of a gain switch.

However, stable SHG output may not be obtained by mere use of the fiber laser in this embodiment. In the structure in which FBGs formed of polarization-maintaining fibers cross each other perpendicularly so as to provide single polarized light as in this embodiment, the loss in the resonator is small and thus pulsed light having a large output can be generated. However, it was confirmed by an experiment that when the SHG element converts the single polarized light, the SHG output is significantly changed.

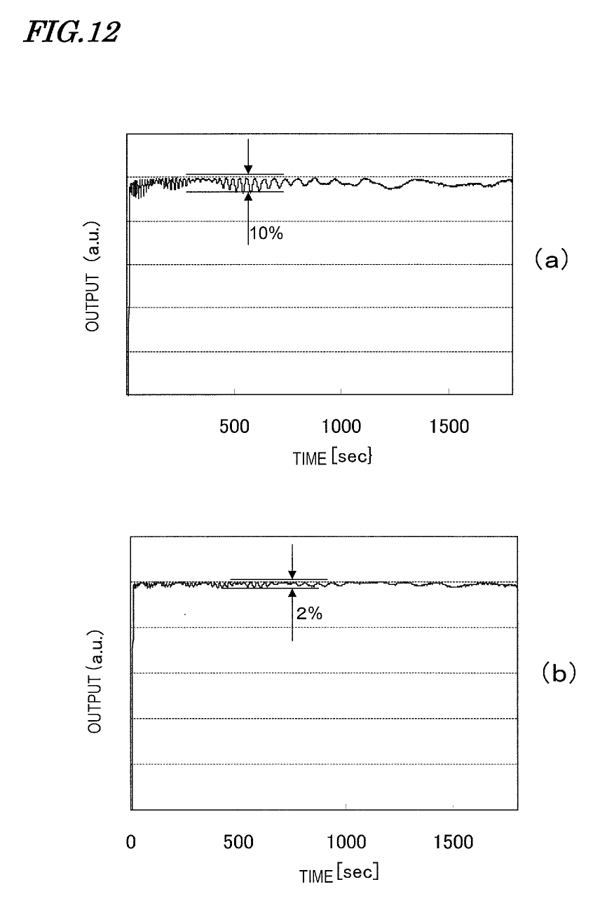

This occurs because the polarization components are slightly coupled to each other when the fibers having polarizations cross each other perpendicularly are coupled to each other. When the polarization-maintaining fibers are joined together by fusion, different polarization components are slightly coupled to each other (e.g., −20 dB or less). Since the fiber laser has a long laser medium, even unnecessary polarization components are amplified in the laser resonator and are output as polarization components which do not contribute to the wavelength conversion. The magnitude of the polarization components which do not contribute to the wavelength conversion occupies about several to several tens of percent. The output of such unnecessary polarization components is changed by external disturbance or in accordance with the laser oscillation condition. When the unnecessary polarization components included in the fiber laser output is changed as time passes, even though the fiber laser output is controlled to be constant, the SHG output converted by the wavelength conversion element is significantly changed. FIGS. 12(a) and 12(b) show measurement results of such a change of the SHG output.

FIG. 12(a) shows the measurement results of a change of the SHG output along time. The SHG output is obtained by converting laser light, which is obtained by continuously oscillating the fiber laser in this embodiment, by use of the wavelength conversion element. The output from the fiber laser was controlled to be kept constant, and the resultant SHG light was measured. FIGS. 12(a) and 12(b) each show a change of the output along time which was measured with the same average output. The output characteristic of the SHG light which is output from the continuously oscillated fiber laser as shown in FIG. 12(a) is considered to be equivalent to the output characteristic of the SHG light which is output from the fiber laser with no high frequency pulses being superimposed. The graph in FIG. 12(a) shows the results of measurement performed from immediately after the laser oscillation. The output change was about 10%. The output was largely changed at the start of the laser oscillation, and kept changing for a length of several minutes to several hours.

By contrast, FIG. 12(b) shows a change of the SHG output, along time, obtained by wavelength conversion of the wavelength of the pulsed light having high frequency being superimposed thereon. Namely, FIG. 12(b) shows a case where pulse oscillation or the like by a gain switch operation is performed and as a result, high frequency pulses equal to or higher than a prescribed level are superimposed on the principal pulse. It was confirmed that with such a structure of the fiber laser in this embodiment, the decrease of the SHG output change is decreased to 2% or less and that the output stability is significantly improved.

A conceivable reason why the SHG output change is suppressed for the laser light of a waveform having superimposing pulses appropriately superimposed thereon is the magnitude of the pulse peak of the superimposing pulses. Since the peak value of the pulse peak of the superimposing pulses is high, the conversion efficiency of the wavelength conversion by a nonlinear optical effect is saturated. It is considered that because of this reason, the output change of the SHG as converted light, which would be caused by fluctuation of the polarization component, is decreased. Another conceivable reason why the change of the SHG output is suppressed is as follows: since the state of light propagating in the fiber is rapidly changed by generation of a pulse having a high frequency superimposed thereon, the fluctuation of the polarization component by external disturbance is suppressed and thus the change of the polarization component is decreased.

As can be seen from the above, when the laser light source in this embodiment is used, single polarized light can be obtained while generation of loss in the resonator is suppressed. Therefore, the output of the gain pulse can be increased. In addition, the SHG output change caused by fluctuation of a polarization component, which would be caused by the structure of the single polarization laser, can be suppressed.

In the above, a PANDA fiber is used as the polarization-maintaining fiber. Any fiber having birefringence ratio such as an elliptical core fiber or the like can be used in substantially the same manner.

As the second grating fiber 4, a double clad fiber is preferable. Reasons for this are that a high coupling efficiency with the pump light source 1 can be realized, and that pumped light of a high output can be injected into the solid-state laser fiber 2.

### Example and Comparative Example

A laser marking device according to the present invention (example) and a conventional laser marking device (comparative example) were used to compare the shapes of the marking dots which are formed by the respective marking devices while the energy density of the laser light to be directed was changed.

A light source of the laser marking device in the conventional example (comparative example) is a Nd:YVO₄ solid-state laser device of a semiconductor-excitation type. This solid-state laser device was used to perform a pulse operation by a Q switch, and the wavelength of the resultant pulsed laser light was converted by the wavelength conversion element to obtain second harmonic. The resonator length was about 1 m, and the pulse width was 90 ns. The laser output was adjusted by an attenuator. By contrast, as the light source in the example, the laser light source shown in FIG. 6(a) was used. The pulse width of the output pulsed laser light was about 100 ns.

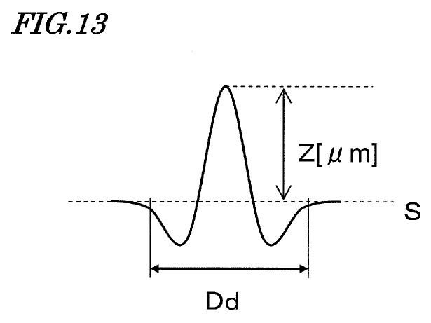

The processing target was a silicon wafer. Marking was performed such that the diameter of the dot to be formed would be 9 μmφ. Now, with reference to FIG. 13, the definition of convexed dot height (height of the convexed part) Z will be described. FIG. 13 is a cross-sectional view of a semiconductor wafer on which a dot is formed. As can be seen from FIG. 13, the dot height Z is a distance from a processed surface S of the semiconductor wafer to the highest point of the elevated part at the center of the dot. Dot diameter Dd is defined by a border between a recessed part formed in a peripheral part of the dot and the flat processed surface S. The dot diameter Dd is actually a diameter of an outer perimeter of a circular dot (including the recessed part) which is observed in a direction perpendicular to the processed surface.

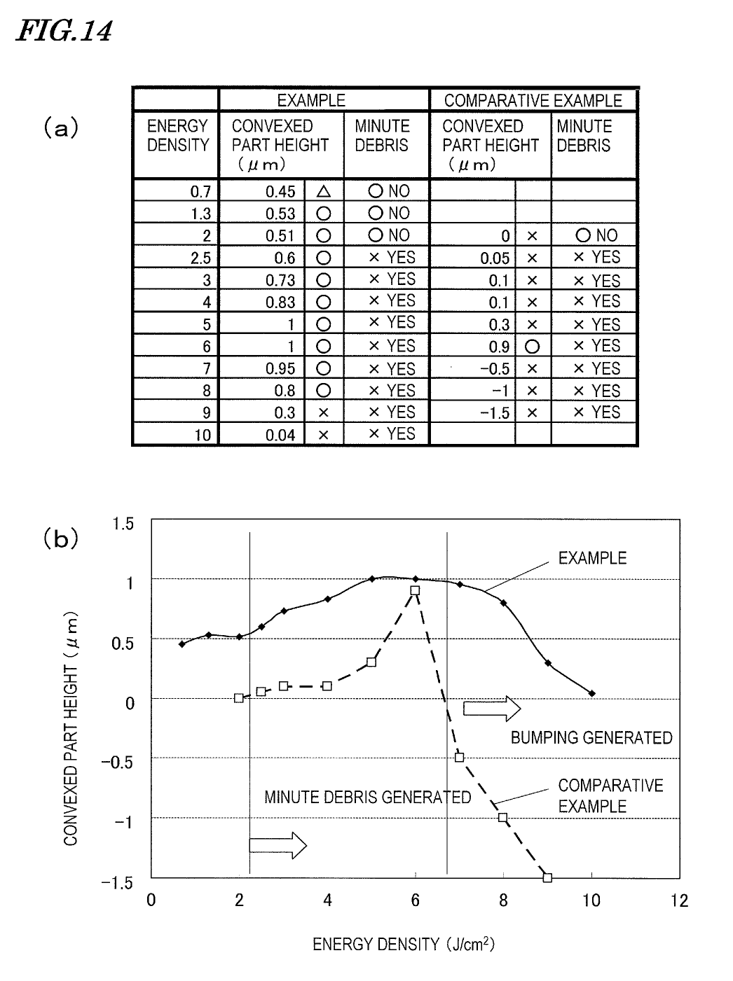

FIG. 14(a) is a table showing the relationship between the energy density, at a light collection point, of laser light directed toward the semiconductor wafer and the dot height Z, and the generation state of minute debris. FIG. 14(b) is a graph showing the data of FIG. 14(a).

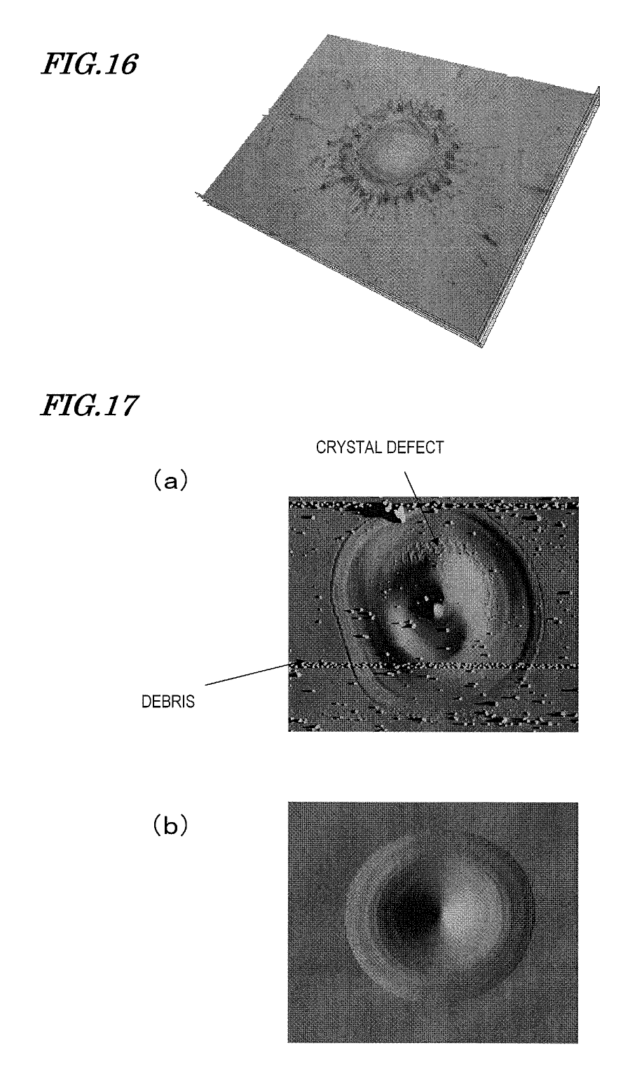

The minute debris are of a nanometer order, and is observed by an AFM. As can be seen from FIG. 14(a), the minute debris were generated both in the example and the comparative example when the irradiation energy density exceeded 2 J/cm². A state where no debris, encompassing minute debris, is generated will be referred to as a “completely debris-free state”. A completely debris-free state was realized at an energy density of 2 J/cm² or lower both in the present invention and the conventional example. Large debris caused by bumping as shown in FIG. 16 were generated when the energy density exceeded 7 J/cm².

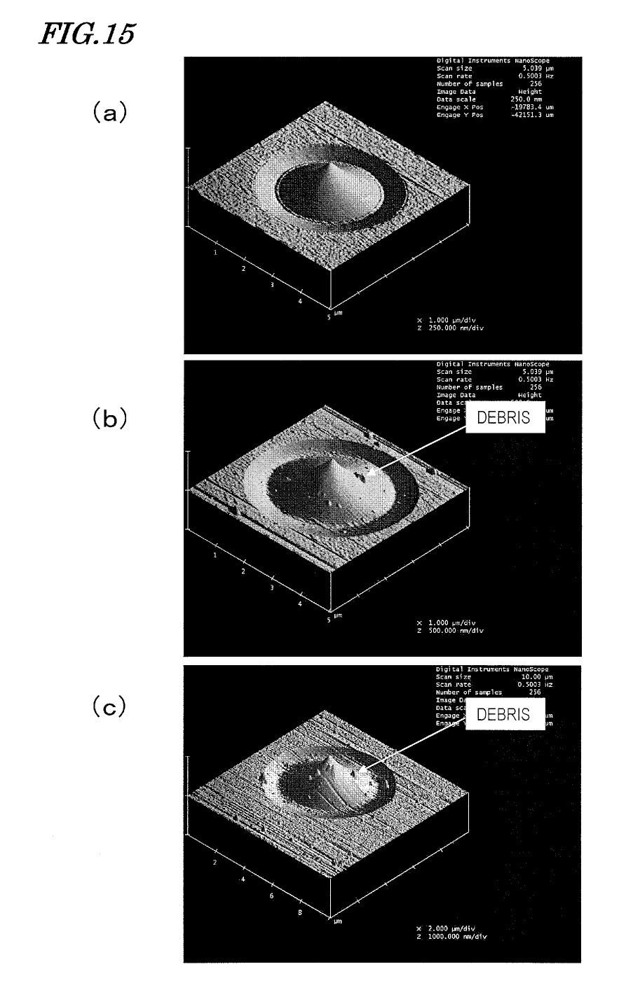

First, dot formation performed in the case where laser light is directed at an energy density of 2 J/cm² or lower, with which a completely debris-free state is realized, will be described. In the comparative example, almost no dot was formed under the conditions of the completely debris-free state. By contrast, in the example, a convexed dot having a height exceeding 0.5 μm was formed in an energy density range of 1 to 2 J/cm². FIG. 15(a) shows an AFM image of a dot formed in the example at an irradiation energy density of 2 J/cm². The formed dot is completely debris-free, and has an extremely high visibility.

Next, dot formation performed with an energy density higher than 2 J/cm² and equal to or lower than 7 J/cm² will be described. In this range of energy density, minute debris are generated. FIGS. 15(b) and 15(c) show the dots with minute debris which were formed in the example when the irradiation energy density was 2.5 J/cm² and 5 J/cm². As can be seen from FIGS. 15(a) through 15(c), as the energy density is increased, the amount of debris is increased.

Depending on the field in which the marking is used, minute debris may be permitted. The dots in the example shown in FIGS. 15(b) and 15(c) can be used as dot marks. However, as can be seen from FIG. 14(b), with the marking device in the comparative example, when the energy density was 5 J/cm² or lower, the dot height was 0.3 μm or less and the visibility was significantly deteriorated. Such a dot cannot be used as a dot mark. When the power density (irradiation energy density) was 7 J/cm² or higher, large debris caused by bumping as shown in FIG. 16 were observed around the dot. A conceivable reason for this is that silicon bumped or silicon melted by transpiration due to the high power density scattered and was attached to the peripheral part in a large amount.

As described above, according to the method in the comparative example, the condition under which a highly visible dot can be formed is limited to 6 J/cm² or the vicinity thereof. Thus, highly precise power control is needed. By contrast, in the example, the height of the convexed part exceeds 0.5 μm in an energy density range of 1 to 9 J/cm². As shown in FIGS. 15(a) through 15(c), convexed dot having an improved visibility can be formed.

As a result of the above, when a laser light source according to the present invention is used, a highly visible convexed dot with little debris can be formed in a wide energy density range of 1 J/cm² or higher and 6 J/cm² or lower. As compared with the conventional art, the dot formation condition can be significantly alleviated. In addition, in an energy density range of 1 J/cm² or higher and 2 J/cm² or lower, a completely debris-free dot, which is conventionally difficult to be formed, can be formed.

FIGS. 17(a) and 17(b) each show an AFM image of a dot observed from just above the wafer. FIG. 17(a) shows a dot formed by the laser marking device in the comparative example at an energy density of 6 J/cm², and FIG. 17(b) shows a dot formed by the laser marking device in the example at an energy density of 1.5 J/cm².

The dot formed by the method in the comparative example has a dot diameter of about 7.2 μm and a height of about 0.8 μm. The shape of the convexed part is bilaterally asymmetric, and the conical shape is distorted. At a surface of the conical shape, minute convexed and concaved parts are observed. The cause of the convexed and concaved parts is crystal defects caused during the formation of the dot. Many minute debris are also observed.

By contrast, the dot formed by the marking device in the example has a dot diameter of about 4 μm and a height of about 0.5 μm. The dot has an ideal conical shape and is highly symmetric. Side surfaces are in a high mirror surface state. No convexed or concaved part, which would be caused by crystal defects, is observed. The surface of the dot is in an ideal mirror surface state. In addition, a completely debris-free state is realized. As can be seen, when the laser marking device in the example is used, a dot mark which is highly visible as compared with the conventional dot mark can be formed.

In the above, a laser light source according to the present invention is used to perform dot marking. The present invention is not limited to this, and is widely usable for laser processing devices for semiconductors. A laser light source according to the present invention is usable for various uses in which it is desired to form a minute convexed part having a good shape on a semiconductor wafer or chip.

For example, the present invention is usable to form a part of components included in a MEMS (Micro Electro Mechanical System) device. According to the present invention, a conical convexed part which is minute and highly symmetrical can be formed on a surface of a semiconductor element. For example, a conductive thin film may be provided on a convexed part and used as an emitter or an electrode for releasing electrons from a tip thereof. In addition, such a precise conical shape may be transferred to a resin or the like, and thus an optical member having many minute recessed parts can be produced.

### Embodiment 2

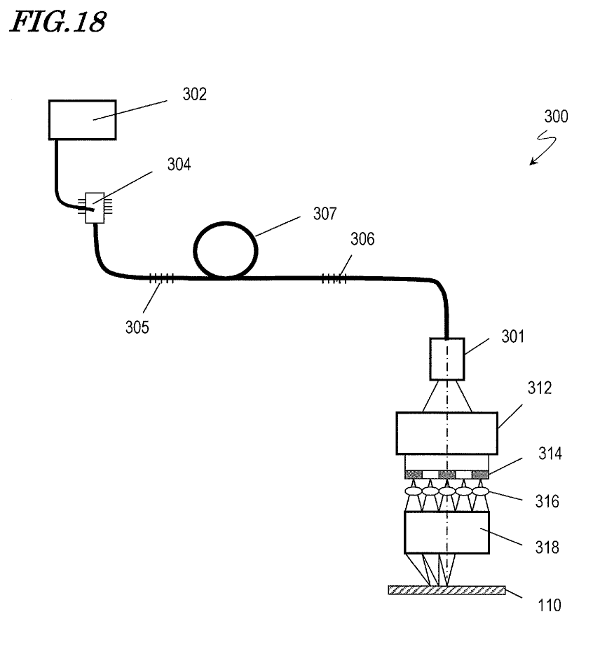

Hereinafter, a marking device 300 using a laser light source in Embodiment 2 according to the present invention will be described. FIG. 18 shows a structure of the marking device 300 for forming a minute dot mark. As shown in FIG. 18, the marking device 300 includes a driving power supply 302, an pumping laser light source 304, a Yb-doped double clad fiber 307, FBGs (fiber Bragg gratings) 305 and 306, an SHG unit 301, a beam shaping unit 312, a liquid crystal mask 314, beam profile conversion means 316, and a lens unit 318. The marking target is a silicon wafer 110.

In this embodiment, the silicon wafer 110 is provided as an example of marking target. The marking target is not limited to the silicon wafer 110, and may be any of various semiconductor wafers. The marking target may be, instead of the silicon wafer 110, a silicon wafer having an oxide film or a nitride film formed thereon, or may be, for example, an epitaxially grown semiconductor wafer, or a semiconductor wafer formed of gallium arsenide, indium-phosphorus compound or the like.

In this embodiment, green light (having Gaussian-shaped energy density distribution) which is output from the SHG unit 301 is first allowed to pass the beam shaping unit 312 to be formed to have a top-hat energy density distribution shape with a generally uniform peak value. The laser light formed such that the energy density distribution is uniform is then directed toward a surface of the liquid crystal mask 314.

Each dot (pixel) of the liquid crystal mask 314 is controlled to be in a light transmission state or a light blocking state, such that a pattern of the dots in the light transmission state and the dots in the light blocking state corresponds to a pattern having a plurality of convexed dot marks to be formed in the semiconductor wafer. The laser light directed toward the liquid crystal mask 314 is transmitted only through the dots in the light transmission state of the mask pattern displayed on the liquid crystal mask 314. At this point, the number of dots on the liquid crystal mask 314 is 5×10 to 10×10, and may be smaller than the total number of convexed dots to be formed on the wafer. In this case, the pattern of the liquid crystal mask 314 may be changed and laser light may be directed a plurality of times such that a desired convexed dot pattern is formed on the wafer. In this process, the convexed dots can be formed at desired positions by moving the wafer or the position to be irradiated. Even in the case where the marking area is divided in this manner, the marking time can be significantly shortened as compared with the case where dots are marked one by one. A method for forming a plurality of convexed dots by use of such a liquid crystal mask is described in, for example, Patent Document 2.

In this embodiment, dot-by-dot laser light which has passed the liquid crystal mask 314 is controlled by the beam profile converters 316 to have an appropriate energy density distribution. The beam profile converters 316 are located in a matrix so as to respectively correspond to the dots located in a matrix in the liquid crystal mask 314. The beam profile converters 316 can reduce deterioration of the quality of the beam and thus can form dots having a good shape. The laser light may be transmitted through the beam profile converters 316 to have a profile thereof changed before passing the liquid crystal mask 314.

The laser light which has passed the beam profile converters 316 is projected in a reduced size by the lens unit 318 and directed to a prescribed position on a surface of the semiconductor wafer 110. As a result, dot marking is performed on a desired position of the semiconductor wafer 110 in a reduced pattern, based on the mask pattern of the liquid crystal mask 314. For forming marks in a micrometer order on the surface of the wafer uniformly, the distance between the marking surface and the light collection lens, or the optical axis alignment, may be adjusted in a micrometer order.

The laser light source 300 in this embodiment converts pulsed laser light generated by use of a gain switch of the fiber laser to green light by the SHG unit 301. As described above, the pulsed light which is output from a laser light source according to the present invention has high frequency superimposing pulses. Therefore, dots of a desired shape can be formed stably by use of pulsed laser light in a wide range of energy density. Therefore, when a plurality of dot marks are to be formed at a time by use of a liquid crystal mask pattern, the dots can be appropriately formed even if the irradiation energy density distribution is dispersed among the dots. In the conventional structure, the number of dots to be marked at a time is limited to about 10×10 in order to guarantee uniformity of inter-dot gaps. With the structure of the present invention, the optical system can be simplified and stabilized. Dot formation can be performed in a wide area including 20×20 dots or more.

Another feature of a laser light source according to the present invention is that superb, completely debris-free convexed dots, which are difficult to be formed by the conventional laser light source, can be formed at a low power density of 2 J/cm² or lower. A problem in dot marking using a liquid crystal mask is deterioration of the liquid crystal mask. When high power light is directed to the liquid crystal mask, the liquid crystal material is deteriorated. Thus, the mask needs to be replaced frequently. By contrast, when a laser light source according to the present invention is used, the irradiation power can be decreased to about ⅓. This extends the life of the liquid crystal mask to twice as longer.

### Embodiment 3

Hereinafter, a method for processing a silicon lens to form convexed and concaved parts by use of a laser light source according to the present invention will be described.

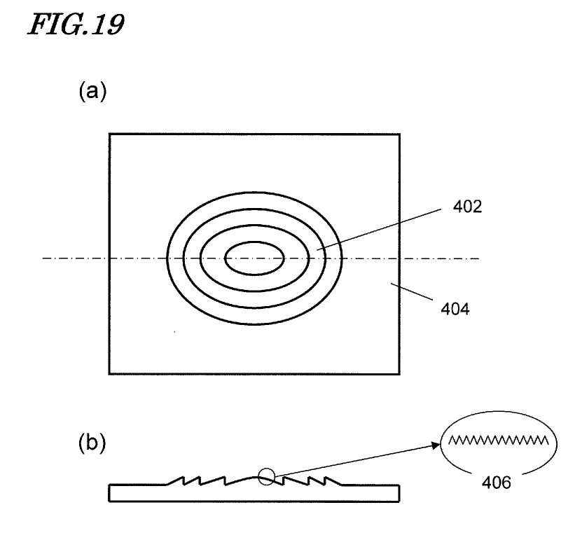

FIGS. 19(a) and 19(b) each show a Fresnel lens 402 on a silicon substrate 404. A surface of Fresnel lens 402 is processed to have minute convexed and concaved parts by use of a laser light source according to the present invention. Silicon is transparent with respect to light in a range from near-infrared light having a wavelength of 1 μm or longer to mid-infrared light, and is used as an optical material. Silicon is processed into a Fresnel lens, which is used for an infrared sensor, a temperature sensor or the like. As a reflection-preventing structure of the Fresnel lens, the minute convexed and concaved parts can be used. A structure referred to as a reflection-preventing structure, which is formed of very minute conical or pyramidal recessed parts located in an array, is provided on a surface of an optical element or an optical component. This reflection-preventing structure acts as a reflection-preventing film for light of a wide range of wavelength.

As shown in FIG. 19(b) in enlargement, a reflection-preventing structure is formed of conical or pyramidal recessed parts 406 located in an array at a pitch shorter than the wavelength of incident light (e.g., pitch of a micrometer order when the incident light is infrared light). When such a reflection-preventing structure is formed on a surface of an optical element or an optical component, the refractive index distribution of the surface is very slowly changed in an optical axis direction of the lens. Incident light having a wavelength longer than the pitch of the conical or pyramidal recessed parts goes inside the optical element or the optical component almost entirely. Therefore, light reflection by the surface of the optical element or the optical component can be prevented.

The reflection-preventing structure has a feature that the reflection-preventing effect is not much decreased even when the incidence angle of the incident light is increased. In this manner, wavelength dependence and incident angle dependence, which are problems of a reflection-preventing film, are solved by forming the reflection-preventing structure on the surface of the optical element or the optical component. In the case of a silicon lens, the wavelength of the incident light is 1 μm or longer. Therefore, the size of a minute structure acting as the reflection-preventing structure is also about 1 μm. The convexed part formed by a laser light source according to the present invention has a mirror-like shape and thus can be used as a reflection-preventing structure of a silicon lens.

In the case where convexed dots are formed by use of a laser light source according to the present invention, the convexed dots have a highly uniform height. Thus, many minute convexed parts having a uniform height can be produced easily. Therefore, the convexed parts can be used to decrease the frictional resistance of a MEMS device, utilizing the uniform height thereof. When such convexed parts are formed uniformly on a contact surface of an operation section of an MEMS device formed of silicon, the contact surface area is decreased by the convexed parts. Therefore, the frictional resistance can be decreased.

### Embodiment 4

The present invention is usable for surface processing of a solar cell. Hereinafter, surface processing of a solar cell using a laser processing device in Embodiment 4 will be described.

For increasing the efficiency of the solar cell, it is very important to promote the introduction of sunlight by decreasing the reflectance at the surface of the cell. For realizing this, it is common to use a minute convexed and concaved structure formed on the surface of the cell and a reflection-preventing film in combination. Various such processes have been proposed and put into practice. According to a common method, a mask pattern is formed on a surface of a silicon substrate, and a convexed and concaved pattern is formed by dry etching. Typically, a pattern of convexed and concaved parts each having a size of several micrometers is formed on the surface of the silicon substrate. However, when the surface of the cell is processed by, for example, plasma etching, surface damages of about several ten to several hundred nanometers are caused in accordance with the plasma power. This requires a process of removing a damaged layer by wet etching to be performed later. In addition, the etching step is a vacuum process. This involves problems that, for example, the processing cost is raised and an extra processing time for providing the vacuum state is required.

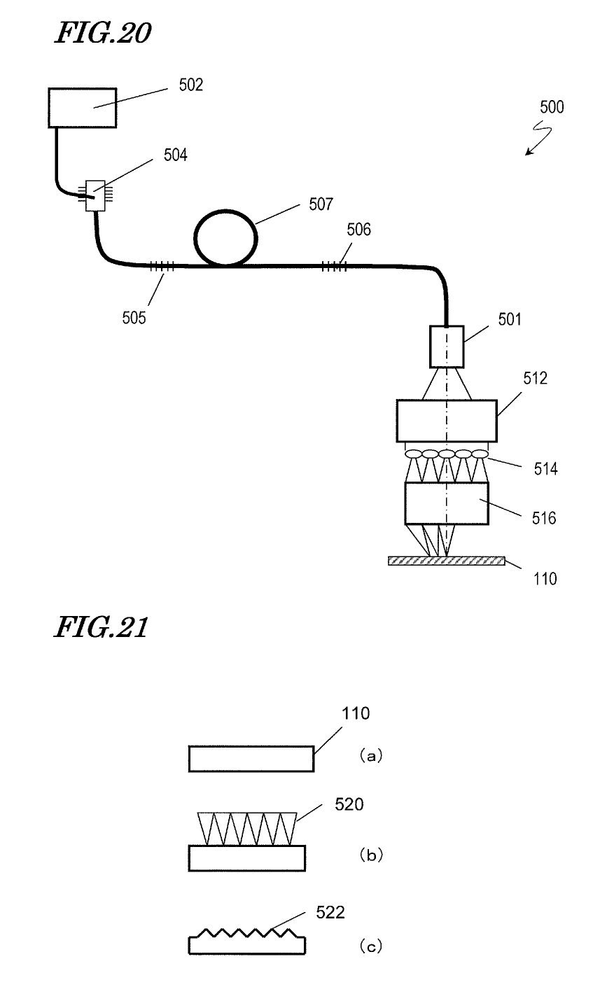

In this embodiment, a laser processing device including a laser light source formed of a fiber laser is used to perform surface processing on a solar cell. As a result, such problems can be solved. Hereinafter, with reference to FIG. 20, a surface processing method for a solar cell in Embodiment 4 will be described.

As shown in FIG. 20, a laser processing device 500 in Embodiment 4 includes an pumping power supply 502, an pumping laser light source 504, a Yb-doped double clad fiber 507, FBGs (fiber Bragg gratings) 505 and 506, an SHG unit 501, a beam shaping unit 512, beam profile conversion means 514, and a lens unit 516. The processing target is the silicon wafer 110.

In this embodiment, the silicon wafer 110 is provided as an example of processing target. In this embodiment, a “wafer” is a general term referring to any type of semiconductor wafer encompassing, in addition to a silicon wafer, a silicon wafer having an oxide film or a nitride film formed thereon, an epitaxially grown semiconductor wafer, and a semiconductor wafer formed of gallium arsenide, indium-phosphorus compound or the like.

In this embodiment, green light (having Gaussian-shaped energy density distribution) which is output from the SHG unit 501 is first allowed to pass the beam shaping unit 512 to be formed to have a top-hat energy density distribution shape with a generally uniform peak value. The laser light formed such that the energy density distribution is uniform is then divided into a plurality of beams by the beam profile conversion means 514. The divided beams are projected in a reduced size by the lens unit 516 and directed to the semiconductor wafer 110.

FIGS. 21(a) through 21(c) show a process of forming a convexed and concaved pattern by use of the laser processing device 500. As shown in FIG. 21(a), first, a surface of the silicon wafer 110 is kept clean. Next, as shown in FIG. 21(b), a laser beam 520 from the laser processing device 500 shown in FIG. 20 is directed in the atmosphere. Owing to this, as shown in FIG. 21(c), while the surface of the silicon wafer 110 is melted and solidified, a convexed and concaved pattern 520 is formed at the surface.

At this point, the focus of the laser light directed toward the wafer 110 corresponds to a plurality of dots formed on the wafer 110. The number of the dots is about 100×100. An area size which can be processed at a time is about 0.5 mm×0.5 mm. In this case, the dot pattern to be formed is divided into a plurality of areas, and the laser irradiation process is performed a plurality of times. Thus, the entirety of the surface of the wafer is processed to have the convexed and concaved pattern. The rate of the dot formation is about 100 kHz, and a surface of a 4-inch wafer can be processed within several seconds. This can significantly increase the processing rate as compared with the vacuum process. The method in Embodiment 4 does not require a vacuum process, and thus can decrease the cost for producing the convexed and concaved pattern. The time for each step is short and the surface is not damaged. Therefore, the time for the production process can be shortened.

The formation of the convexed and concaved pattern which is performed by use of a laser light source in this embodiment includes the step of melting and solidifying silicon. As described above, there are very few remaining solid parts in the melted pool as described above. Therefore, generation of crystal defects, which would be caused when the melted pool is solidified, can be suppressed.

Characteristics of a solar cell are significantly deteriorated by crystal defects at a surface thereof. This requires a complicated step of, for example, removing the damaged layer by etching to be performed. By contrast, when a laser light source according to the present invention is used, the number of crystal defects is significantly decreased, and thus the photoelectric conversion efficiency of the solar cell can be improved. This effect is more conspicuous when polycrystalline silicon is used. A solar cell formed by use of polycrystalline silicon can be formed at low cost, but has many crystal defects and thus has a poor efficiency. By contrast, the process of forming the convexed and concaved pattern by use of a laser light source according to the present invention allows large crystal grains with few crystal defects to be formed in the step of melting and solidifying the surface. Owing to this, the efficiency of the solar cell can be significantly improved.

### INDUSTRIAL APPLICABILITY

When a laser light source according to the present invention is used to perform laser marking, a melted pool generated at a surface of a semiconductor material by irradiation with a pulsed laser beam can be made uniform. Owing to this, highly visible minute dots can be formed. Thus, the laser light source according to the present invention is useful for a laser marking device for marking an ID on a semiconductor material.

### REFERENCE SIGNS LIST

Laser marking device
100 Laser light source
101 Wavelength conversion element
102 Driving power supply
103 Fundamental wave
104 Pumping LD
105, 106 Fiber grating
107 Double clad fiber
108 Scan mirror
109 Stage
110 Semiconductor wafer
112 Lens
113 Second harmonic
114 Attenuator
115 Temperature controller
150 Laser resonator
201 Laser light
202 Melted pool
203 Solidified part
204 Remaining solid part

1. A laser light source, comprising:
a laser resonator including a fiber containing a laser active medium and fiber gratings coupled to each of two ends of the fiber;
a pumping laser light source for emitting pump light into the laser resonator;
a driving current supply circuit for supplying a pulse-like driving current to the pumping laser light source; and
a wavelength conversion element for converting a wavelength of laser light which is output from the laser resonator;
wherein:
the laser resonator generates laser light including a principal pulse and a plurality of superimposing pulses which are superimposed on the principal pulse, in accordance with incidence of the pump light; and
converted light having the wavelength of each of the principal pulse and the superimposing pulses shortened is generated by the wavelength conversion element.

2. The laser light source of claim 1, wherein the laser resonator performs laser oscillation in a plurality of longitudinal modes and allows the plurality of longitudinal modes to interfere with each other to form the plurality of superimposing pulses.

3. The laser light source of claim 1, wherein:
the pumping laser light source emits the pump light having a rectangular waveform to the laser resonator based on the driving current; and
the laser resonator performs pulsed oscillation by the pump light having the rectangular waveform.

4. The laser light source of claim 3, wherein:
when the laser resonator performs the pulsed oscillation, a refractive index of the laser resonator is changed, and the change of the refractive index of the laser resonator changes an effective resonator length of the laser resonator; and
a frequency shift of the laser light caused by the change of the effective resonator length is larger than an inter-longitudinal mode interval of the laser resonator.

5. The laser light source of claim 1, wherein:
the effective resonator length of the laser resonator is changed in accordance with a temperature change of the laser resonator; and
a frequency shift of the laser light caused by the change of the effective resonator length is larger than an inter-longitudinal mode interval of the laser resonator.

6. The laser light source of claim 1, wherein an oscillation spectral width Δfa of the laser resonator is larger than 1 GHz and smaller than a frequency permission degree Δfs at which the wavelength conversion element realizes a prescribed conversion efficiency.

7. The laser light source of claim 6, wherein the frequency permission degree Δfs at which the wavelength conversion element realizes the prescribed conversion efficiency is larger than 1 GHz.

8. The laser light source of claim 1, wherein an oscillation spectral width Δfa of the laser resonator is larger than m·df, which is a logical product of the inter-longitudinal mode interval df and a number m of the longitudinal modes, and is smaller than a frequency permission degree Δfs at which the wavelength conversion element realizes a prescribed conversion efficiency.

9. The laser light source of claim 1, wherein the wavelength conversion element generates harmonic of the laser light which is output from the laser resonator.

10. The laser light source of claim 1, further comprising temperature retaining means for retaining a temperature of the wavelength conversion element at a prescribed level.

11. The laser light source of claim 10, wherein the temperature retaining means retains the temperature of the wavelength conversion element at a level at which the conversion efficiency of the wavelength conversion element is decreased to a value in a range of 5% to 50% of a maximum value.

12. A laser processing device for irradiating a semiconductor wafer or a semiconductor chip by use of the semiconductor wafer with laser light having a wavelength determined in accordance with a material of the semiconductor wafer, to melt a surface of the semiconductor wafer and thus to form a convexed part; the laser processing device comprising:
the laser light source of claim 1; and
an optical system for irradiating the semiconductor wafer or the semiconductor chip with the laser light which is output from the laser light source.

13. A semiconductor processing method, comprising the steps of:
preparing a semiconductor; and
irradiating a surface of the semiconductor with pulsed laser light emitted from a laser light source to form a convexed part on the surface of the semiconductor;
wherein the laser light source is the laser light source of claim 1.
